(19) United States
(12) Patent Application Publication
(10) Pub. No.: US 2022/0320010 A1
(43) Pub. Date: Oct. 6, 2022

(54) SEMICONDUCTOR DEVICE AND MANUFACTURING METHOD THEREOF

(71) Applicant: Amkor Technology Singapore Holding Pte. Ltd., Singapore (SG)

(72) Inventors: Jin Young Kim, Seoul (KR); Keun Soo Kim, Yongin-si, Gyeonggi-do (KR); Byong Jin Kim, Bucheon-si, Gyeonggi-do (KR); Jae Yoon Kim, Jeonju-si, Jeollabuk-do (KR); Do Hyun Na, Seoul (KR); Hyun Il Moon, Seoul (KR); Dae Byong Kang, Seoul (KR)

(21) Appl. No.: 17/843,618

(22) Filed: Jun. 17, 2022

Related U.S. Application Data
(63) Continuation of application No. 14/995,806, filed on Jan. 14, 2016, now abandoned.

(30) Foreign Application Priority Data
Jan. 16, 2015 (KR) 10-2015-0007776
Jan. 29, 2015 (KR) 10-2015-0014328

(51) Int. Cl. H01L 23/552; H01L 23/538; H01L 23/31; H01L 21/48; H01L 23/498; H01L 23/00

(52) U.S. Cl. CPC H01L 23/552; H01L 23/5384; H01L 23/3121; H01L 21/486; H01L 23/49861; H01L 23/5389; H01L 24/97; H01L 2924/15311; H01L 23/49816; H01L 2924/19011; H01L 2224/16227; H01L 2224/32245; H01L 2224/92244; H01L 2924/0002; H01L 2224/12105; H01L 2924/181; H01L 2223/6677; H01L 2224/32225; H01L 2224/97; H01L 2224/04105; H01L 2224/73267; H01L 2924/3025; H01L 2224/19

(57) ABSTRACT

A selectively shielded and/or three-dimensional semiconductor device and a method of manufacturing thereof. For example and without limitation, various aspects of this disclosure provide a semiconductor device that comprises a composite plate for selective shielding and/or a three-dimensional embedded component configuration.

### CROSS-REFERENCE TO RELATED APPLICATIONS/INCORPORATION BY REFERENCE

The present application makes reference to, claims priority to, and claims the benefit of Korean Patent Application No. 10-2015-0007776, filed on Jan. 16, 2015 in the Korean Intellectual Property Office, and Korean Patent Application No. 10-2015-0014328, filed on Jan. 29, 2015 in the Korean Intellectual Property Office, the contents of each which are hereby incorporated herein by reference in their entirety.

### BACKGROUND

Present methods for forming various semiconductor devices, for example three-dimensional and/or shielded semiconductor packages are inadequate, for example unnecessarily expensive and/or resulting in a semiconductor package having dimensions that are too large. Further limitations and disadvantages of conventional and traditional approaches will become apparent to one of skill in the art, through comparison of such approaches with the present disclosure as set forth in the remainder of the present application with reference to the drawings.

### BRIEF DESCRIPTION OF SEVERAL VIEWS OF THE DRAWINGS

FIG. 1 is a cross-sectional view illustrating an example semiconductor device in accordance with various aspects of the present disclosure.

FIG. 2 is a flow diagram illustrating an example method of manufacturing the example semiconductor device of FIG. 1.

FIGS. 3A to 31 are cross-sectional views illustrating various aspects of the example method shown in FIG. 2.

FIG. 4 is a cross-sectional view illustrating an example semiconductor device in accordance with various aspects of the present disclosure.

FIG. 5 is a flow diagram illustrating an example method of manufacturing the example semiconductor device of FIG. 4.

FIG. 6 is a cross-sectional view illustrating various aspects of the example method shown in FIG. 5.

FIG. 7 is a cross-sectional view illustrating an example semiconductor device in accordance with various aspects of the present disclosure.

FIG. 8 is a cross-sectional view illustrating an example semiconductor device in accordance with various aspects of the present disclosure.

FIG. 9 is a flow diagram illustrating an example method of manufacturing the example semiconductor devices of FIGS. 7 and/or 8.

FIGS. 10A to 10K are cross-sectional views illustrating various aspects of the example method shown in FIG. 9.

FIG. 11 is a flow diagram illustrating an example method of manufacturing the example semiconductor devices of FIGS. 7 and/or 8.

FIGS. 12A to 12H are cross-sectional views illustrating various aspects of the example method shown in FIG. 11.

### SUMMARY

Various aspects of this disclosure provide a selectively shielded and/or three-dimensional semiconductor device and a method of manufacturing thereof. For example and without limitation, various aspects of this disclosure provide a semiconductor device that comprises a composite plate for selective shielding and/or a three-dimensional embedded component configuration.

### DETAILED DESCRIPTION OF VARIOUS ASPECTS OF THE DISCLOSURE

The following discussion presents various aspects of the present disclosure by providing examples thereof. Such examples are non-limiting, and thus the scope of various aspects of the present disclosure should not necessarily be limited by any particular characteristics of the provided examples. In the following discussion, the phrases “for example,” “e.g.,” and “exemplary” are non-limiting and are generally synonymous with “by way of example and not limitation,” “for example and not limitation,” and the like.

As utilized herein, “and/or” means any one or more of the items in the list joined by “and/or”. As an example, “x and/or y” means any element of the three-element set {(x), (y), (x, y)}. In other words, “x and/or y” means “one or both of x and y.” As another example, “x, y, and/or z” means any element of the seven-element set {(x), (y), (z), (x, y), (x, z), (y, z), (x, y, z)}. In other words, “x, y and/or z” means “one or more of x, y, and z.”

The terminology used herein is for the purpose of describing particular examples only and is not intended to be limiting of the disclosure. As used herein, the singular forms are intended to include the plural forms as well, unless the context clearly indicates otherwise. It will be further understood that the terms “comprises,” “includes,” “comprising,” “including,” “has,” “have,” “having,” and the like when used in this specification, specify the presence of stated features, integers, steps, operations, elements, and/or components, but do not preclude the presence or addition of one or more other features, integers, steps, operations, elements, components, and/or groups thereof.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present disclosure. Similarly, various spatial terms, such as “upper,” “lower,” “side,” and the like, may be used in distinguishing one element from another element in a relative manner. It should be understood, however, that components may be oriented in different manners, for example a semiconductor device may be turned sideways so that its “top” surface is facing horizontally and its “side” surface is facing vertically, without departing from the teachings of the present disclosure. Additionally, the term “on” will be utilized in the document to mean both “on” and “directly on” (e.g., with no intervening layer).

In the drawings, various dimensions (e.g., layer thickness, width, etc.) may be exaggerated for illustrative clarity. Additionally, like reference numbers are utilized to refer to like elements throughout the discussions of various examples.

Various aspects of the present disclosure may, for example, provide a semiconductor device, and a method of manufacturing thereof, that is capable of simultaneously providing communication from an antenna disposed therein while shielding various components from electromagnetic waves. For example, a metal pattern of a composite plate may be utilized as a shield, where a first portion of the composite plate may be configured to block electromagnetic waves and a second portion of the composite plate may be configured to pass electromagnetic waves.

Various aspects of the present disclosure may also, for example, provide a semiconductor device, and a method of manufacturing thereof, comprising a substrate with a reduced thickness. For example, an example substrate may comprise a thin composite plate comprising a dielectric layer and a metal pattern, through which electrical connections may be provided, for example instead of utilizing a thick metal substrate for shielding electromagnetic waves.

Various aspects of the present disclosure may further, for example, provide a semiconductor device, and a method of manufacturing thereof, configured to provide selective shielding of electromagnetic waves and comprising electronic devices laminated in a stack, wherein the semiconductor device comprises one or more a conductive vias.

Various aspects of the present disclosure may, for example, provide a semiconductor device, and a method of manufacturing thereof, comprising a built-in semiconductor die and another component that is three-dimensionally mounted (e.g., vertically displaced from the built-in semiconductor die) at a position close to the built-in semiconductor die, a three-dimensional (e.g., vertical, vertical and horizontal, etc.) connection between the built-in semiconductor die and the other component, and a structure seating the built-in semiconductor die on a thermal dissipation pad. Selective shielding may also, for example, be provided with a conductive layer.

Various aspects of the present disclosure may provide a method of manufacturing a semiconductor device, and a semiconductor produced thereby. The method may, for example, comprise: forming a composite plate (e.g., a composite think plate) comprising a metal pattern and a dielectric layer, where the metal pattern is exposed to a first surface of the composite plate; attaching a semiconductor die by coupling a second surface of the semiconductor die on the first surface of the composite plate, where a plurality of conductive (or contact) pads (e.g., bond pads) are provided on a first surface of the semiconductor die; forming an insulation layer to cover (e.g., completely cover) the semiconductor die and the first surface of the composite plate; forming a conductive layer by, at least in part, forming via holes (or apertures) through the insulation layer to expose the plurality of conductive pads of the semiconductor die to the outside through the insulation layer, and forming one or more conductive layers on the first surface of the insulation layer and in the via holes that are electrically connected to the plurality of conductive pads exposed to the outside through the via holes in the insulation layer; and forming interconnection structures (e.g., conductive bumps) on the one or more conductive layers formed on the insulation layer.

Various aspects of the present disclosure may also provide a semiconductor device, and a manufacturing method thereof, that comprises: a composite plate comprising a metal pattern and a dielectric layer interposed between conductors of the metal pattern, where the metal pattern is exposed at a first surface of the composite plate and at a second surface of the composite plate opposite the first surface; a semiconductor die having a second surface coupled to (e.g., seated on) the first surface of the composite plate and a first surface comprising a plurality of conductive pads (e.g., bond pads); an insulation layer covering the semiconductor die and the first surface of the composite plate and exposing the plurality of conductive pads of the semiconductor die to the outside through via holes (or apertures) in the insulation layer; a conductive layer formed on a first surface of the insulation layer and electrically connected to the conductive pads through conductive material in the via holes; and a conductive bump formed on and electrically connected to the conductive layer.

Various aspects of the present disclosure may further provide a semiconductor device, and a manufacturing method thereof, with a built-in semiconductor die and three dimensional connection structure that comprises: a first conductive layer disposed in a first direction (e.g., in a horizontally or laterally) and formed of a metal or other conductive material; a semiconductor die formed on an upper part of the first conductive layer; an insulation layer formed to surround the semiconductor die; and a second conductive layer electrically connected to at least one of the first conductive layer and the semiconductor die through conductive vias extending through the insulation layer in a second direction (e.g., vertically) perpendicular to the first direction.

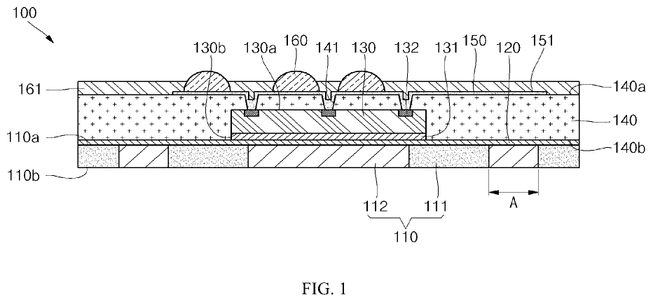

Referring to FIG. 1, such figure shows a cross-sectional view illustrating an example semiconductor device 100 in accordance with various aspects of the present disclosure. As shown in FIG. 1, the example semiconductor device 100 comprises a composite plate 110 (e.g., a composite thin plate), a stress relieving layer 120 (e.g., a stress-relieving film) on the composite plate 110, a semiconductor die 130 on the stress relieving layer 120, an insulation layer 140 covering the semiconductor die 130 and/or the stress relieving layer 120, a conductive layer 150 (which may also be referred to herein as a rewiring layer or redistribution layer, or a portion thereof) electrically connected to the semiconductor die 130, a dielectric layer 161 on the conductive layer 150, and an interconnection structure 160 (e.g., a package interconnection structure, a conductive bump, etc.) electrically coupled to the conductive layer 150 through apertures in the dielectric layer 161.

The composite plate 110 may, for example, comprise a metal pattern 111 and a dielectric layer 112 interposed between portions (e.g., between pads, traces, etc.) of the metal pattern 111, for example to electrically isolate various portions of the metal pattern 111. The composite plate 110 may, for example, comprise a flat plate structure having a first surface 110a (e.g., a top surface) and a second surface 110b (e.g., a bottom surface) opposite the first surface 110a. The first surface 110a and/or the second surface 110b may be planar (or flat).

The metal pattern 111 may, for example, comprise a pattern layer formed of a metal (e.g., copper, etc.) or other conductive material with a predetermined (e.g., constant) thickness. The dielectric layer 112 may, for example, be positioned in regions of the composite plate 110 that are not occupied by the metal pattern 111 (e.g., between pads, traces, lands, etc., of the metal pattern 111). The dielectric layer 112 may, for example, comprise any of a variety of organic dielectric materials (e.g., polyimide (PI), benzo cyclo butane (BCB), poly benz oxazole (PBO), bismaleimide triazine (BT), a phenolic resin, epoxy, etc.). In various implementations, however, an inorganic dielectric may also be utilized (e.g., Si₃N₄, SiO₂, SiON, etc.). Since the thickness of the dielectric layer 112 may be identical to that of the metal pattern 111, the composite plate 110 may have a constant (e.g., predetermined) thickness. For example, the composite plate 110 may comprise a first planar surface 110a comprising a first planar surface of the metal pattern 111 and a first planar surface of the dielectric layer 112, and a second planar surface 110b comprising a second planar surface of the metal pattern 111 and a second planar surface of the dielectric layer 112.

In an example implementation, the metal pattern 111 may comprise a pattern (e.g., a mesh or screen, an array of parallel lines or fingers, an array of pads, etc.) such that the composite plate 110 may selectively shield electromagnetic waves applied to and/or emitted from the semiconductor die 130 (and/or an antenna attached thereto), or other component of the semiconductor device 100. For example, in relation to the composite plate 110, the metal pattern 111 may be provided in a first one or more areas for shielding electromagnetic waves applied to and/or emitted from the semiconductor die 130 (and/or an antenna attached thereto), and the dielectric layer 112 may be provided in a second one or more areas for which electromagnetic shielding is not required (or desired).

The stress relieving layer 120 (e.g., a film, stiff planar layer, etc.) covers the first surface 110a (e.g., top surface) of the composite plate 110. The stress relieving layer 120 may, for example, be interposed between the composite plate 110 and the semiconductor die 130. Additionally, the stress relieving layer 120 may be interposed between the composite plate 110 and the insulation layer 140. The stress relieving layer 120 may cover the entire first surface 110a of the composite plate 110, but may also cover most of the first surface 110a, at least a portion of the first surface 110a to be covered by the die 130, etc. The stress relieving layer 120 may, for example, comprise an insulating material (e.g., any or the organic and/or inorganic materials discussed herein, etc.). The stress relieving layer 120 may be incorporated to prevent or substantially reduce warpage, for example due to a thermal stress (or expansion) difference between the composite plate 110 and the semiconductor die 130, insulation layer 140, and/or other components of the semiconductor device 100. The stress relieving layer 120 may, for example, primarily function to relieve stress and might, for example in various example implementations, perform no significant electronic purpose.

The semiconductor die 130 is attached to the stress relieving layer 120 utilizing a die attach film 131 or other adhesive member (or layer). The die attach film 131 may, for example, comprise a double-sided tape, a first side of which (e.g., a top side) is attached to the semiconductor die 130, and a second side of which (e.g., a bottom side) is attached to the stress relieving layer 120. The semiconductor die 130 may, for example, comprise a generally planar shape, comprising a flat (or planar) first surface 130a (e.g., a top surface), a flat (or planar) second surface 130b (e.g., a bottom surface) opposite the first surface 130a, and side (or lateral) surfaces extending between the first surface 130a and the second surface 130b. The semiconductor die 130 may, for example, comprise a plurality of conductive pads 132 (e.g., bond pads, etc.) on the first surface 130a. The conductive pads 132 may also be referred to herein as contact pads 132. The second surface 130b of the semiconductor die 130 may be attached to the stress relieving layer 120 with the die attach film 131. The first surface 130a of the semiconductor die 130 may, for example, comprise an active surface (or front side) of the die 130, and the second surface 130b of the semiconductor die 130 may comprise an inactive surface (or back side) of the die 130. The plurality of conductive pads 132 of the semiconductor die 130 may, for example, be electrically connected to the conductive layer 150 through via holes in the insulation layer 140.

The insulation layer 140 may, for example, cover the semiconductor die 130 and the stress relieving layer 120. For example, the insulation layer 140 may cover the entire stress relieving layer 120, the first surface 130a of the semiconductor die 130, and the side surfaces of the semiconductor die 130 that extend between the first surface 130a and the second surface 130b. The insulation layer 140 may thus protect the semiconductor die 130 and/or other components of the semiconductor device 100 from an external environment (e.g., physical shock, temperature, moisture, etc.). Note that in an alternative configuration, the first surface 130a of the semiconductor die 130 may be exposed from the insulation layer (e.g., coplanar with a top surface of the insulation layer 140, exposed through an aperture in a top surface of the insulation layer 140 where the top surface is elevated above the first surface 130a of the semiconductor die 130, etc.

The insulation layer 140 may, for example, comprise a Build-up Film (BF) (e.g., a resin layer, prepreg layer (e.g., an epoxy-impregnated fiber matrix, etc.), epoxy layer, dry film, etc.). The insulation layer 140 may comprise any one or more of a variety of materials (e.g., BF, a polymer, a polymer composite material (such as epoxy resin with filler, epoxy acrylate with filler, or polymer with a proper filler), polyimide (PI), benzo cyclo butene (BCB), poly benz oxazole (PBO), bismaleimide triazine (BT), and phenolic resin, etc.).

The insulating layer 140 may, for example, comprise a plurality of via holes 141 that extend from the first surface 140a (e.g., top surface) of the insulation layer 140 to the conductive pads 132 of the semiconductor die 130. The via holes 141 may thus expose the conductive pads 132 of the semiconductor die 130 to the outside.

The conductive layer 150 may, for example, be on the first surface 140a (e.g., top surface) of the insulation layer 140 and may be electrically connected to the plurality of conductive pads 132 of the semiconductor die 130 exposed to the outside through respective via holes 141. Additionally, the conductive layer 150 may extend (e.g., horizontally or laterally) along the first surface 140a of the insulation layer 140. The conductive layer 150 may, for example, comprise copper and/or any of a variety of materials (e.g., Cu, Au, Ag, Ni, Al, Ti, Cr, NiV, CrCu, TiW, TiN, alloys thereof, etc.), but the scope of this disclosure is not limited thereto.

In an example implementation, the conductive layer 150 may further comprise an antenna 151 (e.g., a coil type antenna, a line type antenna, etc.) that is electrically connected to at least one of the plurality of conductive pads 132 of the semiconductor die 130 and that extends (e.g., horizontally or laterally) along the first surface 140a of the insulation layer 140. The antenna 151 may be positioned in (or over) an area A corresponding to the dielectric layer 112 of the composite plate 110 (e.g., vertically directly over the dielectric layer 112) so that electromagnetic waves travelling to and/or from the antenna 151 are not shielded by the metal pattern 111 of the composite plate 110. For example, the antenna 151 and the dielectric layer 112 may be positioned along a same vertical line in FIG. 1. Additionally for example, the area A may be the same as or larger than the area of the antenna 151.

The interconnection structure 160 (e.g., a package interconnection structure, conductive ball or bump, solder ball or bump, metal pillar or post, land, lead, etc.) is on the conductive layer 150 (e.g., and electrically connected to the semiconductor die 130 through the conductive layer 150. For example, the interconnection structure 160 may be soldered to the conductive layer 150, plated on the conductive layer 150, adhesively attached to the conductive layer 150, etc.

A dielectric layer 161 (which may also be referred to herein as a passivation layer) may, for example, cover the conductive layer 150 in an area where the interconnection structure 160 (or plurality thereof) is not formed. The dielectric layer 161 may, for example, cover the conductive layer 150 and the first surface 140a of the insulation layer 140, thereby preventing the conductive bump from flowing to undesired locations during the forming and/or later reflowing of the interconnection structure 160 and also protecting the conductive layer 150 from the external environment. The dielectric layer 161 may comprise any one or more of a variety of materials (e.g., solder resist, polymer resin, insulating resin, polyimide (PI), benzo cyclo butane (BCB), poly benz oxazole (PBO), bismaleimide triazine (BT), a phenolic resin, epoxy, etc.), but the scope of this disclosure is not limited thereto.

The interconnection structure 160 may, for example, operate as an input and/or output terminal or connection, which provides for the semiconductor device 100 to be mounted on an external device, external circuit board, etc. The interconnection structure 160 may comprise any of a variety of materials (e.g., Sn, Pb, Cu, Au, Ag, Ni, Al, Ti, Cr, NiV, CrCu, TiW, TiN, alloys thereof, etc.), but the scope of this disclosure is not limited thereto.

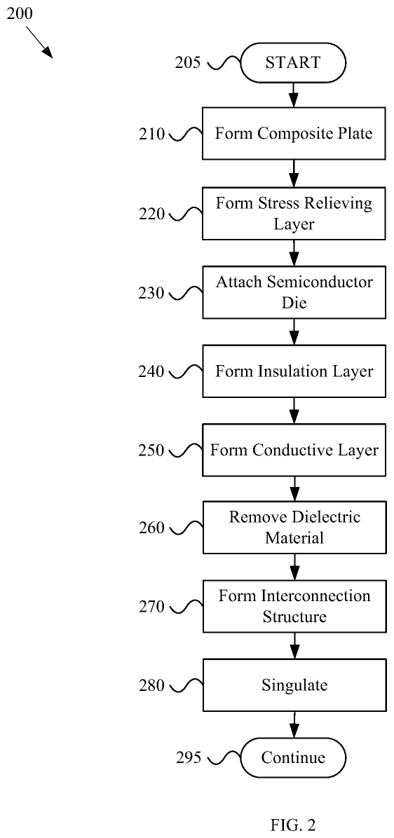

Referring to FIG. 2, such figure shows a flow diagram illustrating an example method 200 of manufacturing the example semiconductor device 100 of FIG. 1. The example manufacturing method 200 may, for example, share any or all characteristics with the other example methods presented herein (e.g., the method 500, method 900, method 1100, etc.).

As shown in FIG. 2, the example manufacturing method 200 may comprise forming a composite plate at block 210, forming a stress relieving layer at block 220, attaching a semiconductor die at block 230, forming an insulation layer at block 240, forming a conductive layer at block 250, removing dielectric material at block 260, forming an interconnection structure at block 270, singulating at block 280, and continuing processing at block 295.

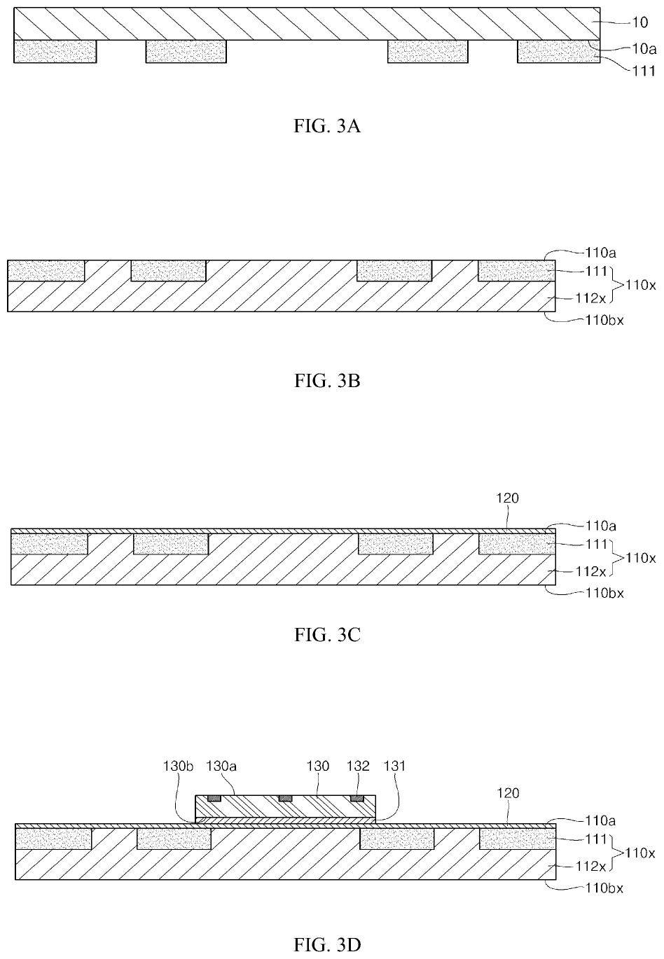

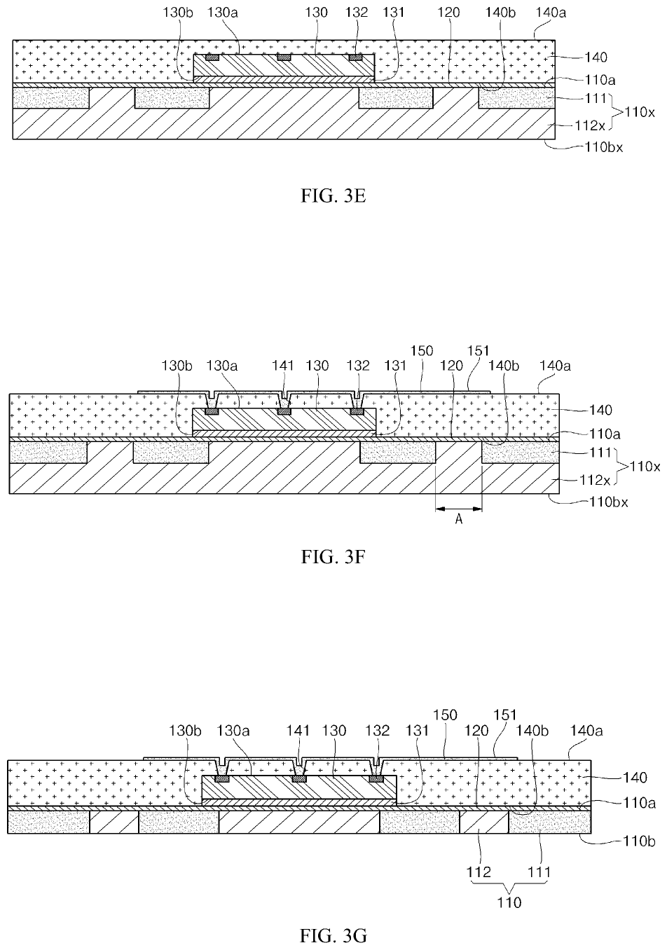

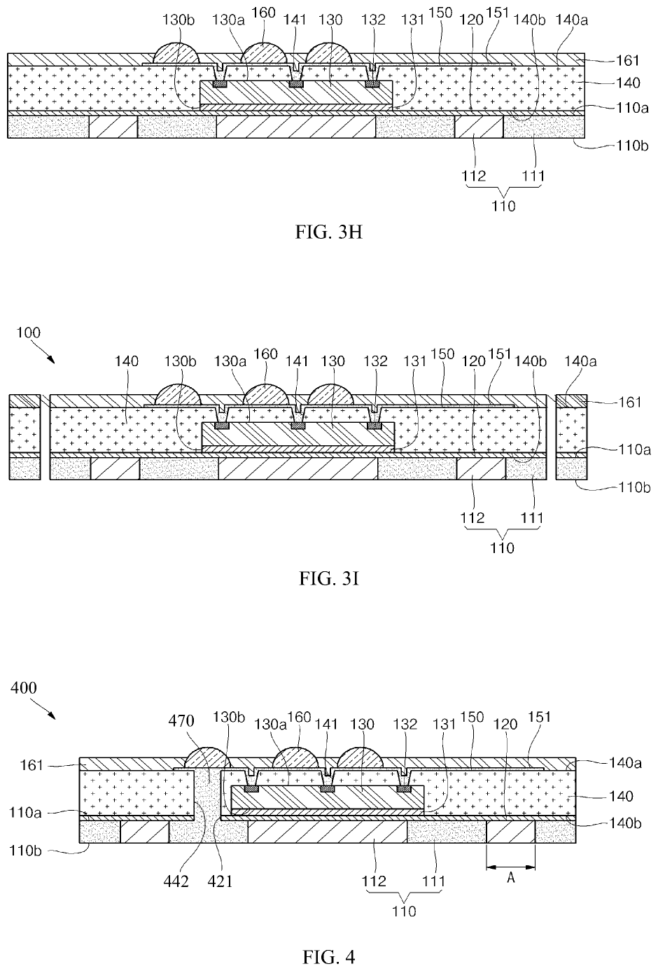

Referring to FIGS. 3A to 31, such figures are cross-sectional views illustrating various aspects of the example method 200 shown in FIG. 2. The example method 200 of manufacturing shown in FIG. 2 will now be discussed with reference to FIGS. 3A to 31.

Referring to FIGS. 3A and 3B, cross-sectional views illustrating the forming of the composite plate at block 210 are shown. During the forming of the composite plate at block 210, which may also be referred to herein as a composite thin plate, a temporary panel 10 (e.g., a plate-shaped temporary panel), which may also be referred to herein as a dummy panel, is prepared (or provided). The temporary panel 10 may, for example, comprise a Copper Clad Laminate (CCL) panel but the present disclosure is not limited thereto. For example, the temporary panel 10 may comprise a glass panel (e.g., a wafer), a silicon panel (e.g., a wafer), a metal panel (e.g., or wafer), etc.

A metal pattern 111 and a dielectric layer 112x are formed to cover a first surface 10a of the temporary panel 10. First, the metal pattern 111 comprising a conductive material (e.g., copper or other metal, etc.) is formed on the first surface 10a of the temporary panel 10. The metal pattern 111 may, for example, comprise one or more layers of any one or more of a variety of materials (e.g., Cu, Au, Ag, Ni, Al, Ti, Cr, NiV, CrCu, TiW, TiN, etc.). Though the metal pattern 111 is generally presented as being metal, the pattern 111 may also be formed of other conductive materials (e.g., conductive epoxies, conductive inks, etc.). The metal pattern 111 may be formed utilizing any one or more of a variety of processes (e.g., electrolytic plating, electroless plating, chemical vapor deposition (CVD), sputtering or physical vapor deposition (PVD), plasma vapor deposition, printing, etc.). The metal pattern 111 may, for example, be formed with a uniform thickness, but need not be.

In an example implementation, a mask pattern (not shown) is formed on the first surface 10a of the temporary panel 10 (e.g., on a seed layer thereof), the metal pattern 111 is formed (e.g., plated, etc.) on the first surface 10a of the temporary panel 10 (or seed layer thereof) exposed to the outside through the mask pattern, and then the mask pattern (and/or uncovered seed layer) is removed (e.g., chemically stripped, etc.), for example leaving just the formed metal pattern 111 on the first surface 10a of the dummy panel 10 as shown in FIG. 3A. Note that conductive materials other than metal (e.g., conductive epoxies or pastes, etc.) may also be utilized. The metal pattern 111 may comprise any of a variety of patterns, for example to perform selective shielding of electromagnetic waves (e.g., a mesh or screen, an array of parallel lines or fingers, and/or an array of pads, etc.). Note that the metal pattern 111 may also comprise traces for communicating signals unrelated to electromagnetic shielding.

After the forming of the metal pattern 111, the dielectric layer 112x is formed to cover the metal pattern 111 (e.g., to cover all surfaces of the metal pattern 111 not covered by the temporary panel 10) and the first surface 10a of the temporary panel 10. The dielectric layer 112x may, for example, comprise any of a variety of organic dielectric materials (e.g., polyimide (PI), benzo cyclo butane (BCB), poly benz oxazole (PBO), bismaleimide triazine (BT), a phenolic resin, epoxy, etc.). In various implementations, however, an inorganic dielectric may also be utilized (e.g., Si₃N₄, SiO₂, SiON, etc.). The dielectric layer 112x may be formed in any of a variety of manners (e.g., printing, spin coating, spray coating, sintering, thermal oxidation, physical vapor deposition (PVD), chemical vapor deposition (CVD), plasma vapor deposition, etc.). Note that depending on the manner in which the metal pattern 111 is formed, the dielectric layer 112x (or at least a portion thereof) may be formed before the metal pattern 111.

After the forming of the metal pattern 111 and the forming of the dielectric layer 112x, which may at this point be referred to as the composite plate 110x, the temporary panel 10 is removed so that the first surface 110a of the composite plate 110x is exposed to the outside. The temporary panel 110 may be removed in any of a variety of manners. For example, the temporary panel 110 may be removed by mechanical peeling, shearing, grinding, etc. The temporary panel 110 may also, for example, be removed by chemical etching, etc. The temporary panel 110 may, for example, be removed in any of the example manners discussed herein with regard to the removal of temporary panels, carriers, and/or other layers. At this point, a second surface 110bx of the composite thin plate 110x opposite the first surface 110a may comprise a lower surface of the dielectric layer 112x.

Referring to FIG. 3C, a cross-sectional view illustrating the forming of the stress relieving layer at block 220 is shown. During the forming of the stress relieving layer (e.g., a film, etc.) at block 220, the stress relieving layer 120 is formed to cover the first surface 110a (e.g., all of the first surface 110a, most of the first surface 110a, at least a portion of the first surface 110a to be covered by the die 130, etc.) of the composite plate 110x exposed to the outside by removing the temporary panel 10 at block 210. The stress relieving layer 120 may comprise any of a variety of materials (e.g., any one or more of the organic and/or inorganic materials discussed herein, etc.). The stress relieving layer 120 may, for example, be incorporated to prevent or substantially reduce warpage, for example due to a thermal stress (or expansion) difference between the composite plate 110 and the semiconductor die 130 to be attached at block 230, the insulation layer to be formed at block 240, and/or any other components of the semiconductor device 100. The stress relieving layer 120 may be formed in any of a variety of manners (e.g., printing, spin coating, spray coating, sintering, thermal oxidation, sputtering or physical vapor deposition (PVD), chemical vapor deposition (CVD), plasma vapor deposition, molding, etc. The thickness of the stress relieving layer 120 and/or the material(s) from which it is made may, for example, be optimized to provide the desired amount of stiffness or stress relieve while having a minimum thickness.

Referring to FIG. 3D, a cross-sectional view illustrating the attaching of the semiconductor die at block 230 is shown. During the attaching of the semiconductor die at block 230, the semiconductor die 130 is coupled to (e.g., seated on, mounted to, attached to, etc.) the stress relieving layer 120. The semiconductor die 130 is coupled to the stress relieving layer 120, for example, using a die attach film 131 or other adhesive member (or layer). The die attach film 131 may comprise any of a variety of characteristics. For example, the die attach film 131 may comprise a preformed adhesive sheet, a printed or otherwise deposited adhesive paste or liquid, etc. In an example implementation, the die attach film 131 may comprise a double-sided tape (e.g., sized to match the die 130, sized greater or less than the die, etc.), a first side of which (e.g., a top side) is adhered to the semiconductor die 130, and a second side of which (e.g., a bottom side) is adhered to the stress relieving layer 120. Such die attach film 131 may, for example, be attached to the die 130 first or to the stress relieving layer 120 first.

The semiconductor die 130 may, for example, comprise a first surface 130a (e.g., a planar top first surface), a second surface 130b (e.g., a planar bottom second surface) opposite the first surface 130a, and side surfaces (e.g., planar side or lateral surfaces) extending between the first surface 130a and the second surface 130b. The semiconductor die 130 may also comprise a plurality of conductive pads 132 (e.g., bond pads, lands, etc.) on the first surface 130a. The second surface 130b of the semiconductor die 130 is shown coupled to the stress relieving layer 120 with the die attach film 131. The first surface 130a of the semiconductor die 130 may, for example, comprise an active surface (or front side) of the die 130, and the second surface 130b of the semiconductor die 130 may comprise an inactive surface (or back side) of the die 130.

Referring to FIG. 3E, a cross-sectional view illustrating the forming of the insulation layer at block 240 is shown. During the forming of the insulation layer at block 240, an insulation layer 140, which may also be referred to herein as a dielectric layer, is formed to cover at least the stress relieving layer 120 and the first surface 130a and side surfaces of the semiconductor die 130. The insulation layer 140 may, for example, comprise a first surface 140a (e.g., a flat or planar first surface), a second surface 140b (e.g., a flat or planar second surface) contacting the stress relieving layer 120, and other surfaces (e.g., other flat or planar surfaces) contacting the first surface 130a and side surfaces of the semiconductor die 130, contacting the die attach film 131, etc.

The insulation layer 140 may, for example, comprise a Build-up Film (BF) (e.g., a resin layer, prepreg layer (e.g., an epoxy-impregnated fiber matrix, etc.), epoxy layer, dry film, etc.). The insulation layer 140 may comprise any one or more of a variety of materials (e.g., BF, a polymer, a polymer composite material (such as epoxy resin with filler, epoxy acrylate with filler, or polymer with proper filler), polyimide (PI), benzo cyclo butene (BCB), poly benz oxazole (PBO), bismaleimide triazine (BT), and phenolic resin, etc.). The insulation layer 140 may be formed in any of a variety of manners (e.g., vacuum lamination and/or hot-pressing, compression molding, transfer molding, liquid encapsulant molding, paste printing, film assisted molding, flooding, curing, etc.).

Referring to FIG. 3F, a cross-sectional view illustrating the forming of the conductive layer at block 250 is shown. The conductive layer 150 may also be referred to as a rewiring layer, a redistribution layer, a signal routing layer, etc.

During the forming of the conductive layer 150 at block 250, one or more via holes 141 are formed in the first surface 140a of the insulation layer 140, thereby exposing one or more respective conductive pads 132 of the semiconductor die 130, and a conductive layer 150 (e.g., a conductive layer) is formed to be connected to the one or more conductive pads 132. The via hole(s) 141 may, for example, be formed by laser ablation, but the scope of this disclosure is not limited thereto.

The conductive layer 150 connected to the one or more of the conductive pads 132 may, for example, be formed to partially extend (e.g., horizontally or laterally) along the first surface 140a of the insulation layer 140. For example, the conductive layer 150 may be formed on the first surface 140a of the insulation layer 140 and may also be electrically connected to the one or more conductive pads 132 of the semiconductor die 130 through the one or more via holes 141. In an example implementation, the conductive layer 150 comprises a plurality of respective conductive traces, each electrically connected to a respective conductive pad 132 through a respective via hole 141 (or aperture) in the insulation layer 140. The conductive layer 150 may, for example, comprise one or more layers of any of a variety of materials (e.g., Cu, Au, Ag, Ni, Al, Ti, Cr, NiV, CrCu, TiW, TiN, etc.). The conductive layer 150 may be formed utilizing any one or more of a variety of processes (e.g., electrolytic plating, electroless plating, chemical vapor deposition (CVD) plasma vapor deposition (PVD), etc.

In an example implementation, the conductive layer 150 may comprise a coil type antenna 151 extending along the first surface 140a of the insulation layer 140. In an example implementation, to allow for desirable transmission and/or reception of electromagnetic radiation at the antenna 151, the antenna 151 may be formed over an area A of the composite plate 110 in which the metal pattern 111 is not formed, so that the desirable electromagnetic waves will not be shielded by the metal pattern 111. For example, the antenna 151 may be formed over the dielectric layer 112 of the composite plate 110.

Note that blocks 240 and/or 250 may be repeated to form a multilayer structure for routing electrical signals to/from the semiconductor die 130 and/or other components (e.g., other components within or outside of the semiconductor device 100).

Referring to FIG. 3G, a cross-sectional view illustrating the removing of dielectric material at block 260 is shown. During the removing of dielectric material at block 260, the metal pattern 111 may be exposed at the second surface 110b of the composite plate 110 by removing at least a portion of the dielectric layer 112 from the second surface 110bx of the composite plate 110 (e.g., as shown at FIG. 3F) to the second surface 110b of the composite plate 110 (e.g., as shown at FIG. 3G). Such removing may be performed in any of a variety of manners (e.g., mechanical grinding, mechanical/chemical removal, etc.). In an example implementation, after such removing, the second surface 110b of the composite thin plate may comprise coplanar surfaces of the metal pattern 111 and the dielectric layer 112. Note that in an alternative implementation, the removal of the dielectric material at block 260 may leave a portion of the dielectric layer 112x covering the second surface (e.g., lower surface) of the metal pattern 111.

Referring to FIG. 3H, a cross-sectional view illustrating the forming of the interconnection structure at block 270 is shown. The interconnection structure 160 may comprise characteristics of any of a variety of different types of interconnection structures (e.g., package interconnection structures, conductive bumps or balls, solder bumps or balls, metal pillars or posts, etc.). The interconnection structure 160 may, for example, comprise a package interconnection structure by which the semiconductor device 100 may be electrically and/or mechanically connected to another device, substrate of a multi-device module, mother board, etc. During the forming of the interconnection structure at block 270, an interconnection structure 160 (or a plurality thereof) is formed on the conductive layer 150. Before the forming of the interconnection structure 160, a dielectric layer 161 (which may also be referred to herein as a passivation layer) may be formed on the conductive layer 150 and on the first surface 140a of the insulation layer 140 in an area other than an area where the interconnection structure 160 is to be formed. For example, during the forming of the interconnection structure at block 270, the dielectric layer 161 may be formed on the conductive layer 150 and the first surface 140a of the insulation layer 140 to expose a partial area of the conductive layer 150 to the outside, and the interconnection structure 160 may then be formed on the conductive layer 150 exposed to the outside. The dielectric layer 161 may comprise one or more of any of a variety of materials (e.g., solder resist, polymer resin, insulating resin, polyimide (PI), benzo cyclo butane (BCB), poly benz oxazole (PBO), bismaleimide triazine (BT), a phenolic resin, epoxy, etc.). The dielectric layer 161 may be formed utilizing one or more of a variety of processes (e.g., liquid coating, taping, printing, spin coating, spray coating, sintering, thermal oxidation, sputtering or physical vapor deposition (PVD), chemical vapor deposition (CVD), plasma vapor deposition, etc.). Note that in an alternative implementation, an interconnection structure 160 (or plurality thereof) may be formed on the conductive layer 150 before the dielectric layer 161 is applied. For example, the dielectric layer 161 may be applied after the interconnection structure 160 is formed, and may cover (e.g., from the side and/or from above) the interconnection structure 160.

Referring to FIG. 3I, a cross-sectional view illustrating the singulating at block 280 is shown. During the singulating at block 280, each individual semiconductor device 100 having at least one semiconductor die 130 is separated by cutting the insulation layer 140, the composite plate 110 (e.g., the metal pattern 111 and/or dielectric layer 112), the stress relieving layer 120, etc. Such singulating may, for example, be performed when the semiconductor device 100 is formed in a panel (or wafer) of such devices. The singulating may be performed in any of a variety of manners (e.g., by mechanical sawing or cutting, by laser cutting, etc.). After such singulating, side (or lateral) surfaces of the insulation layer, the composite plate 110 (e.g., the metal pattern 111 and/or dielectric layer 112), the stress relieving layer 120, etc. may be coplanar.

The example method 200 may, for example at block 295, comprise performing continued processing. Such continued processing may, for example, comprise coupling the device 100 to one or more other devices, cleaning processes, marking processes, packing and/or shipping processes, etc.

Referring to FIG. 4, a cross-sectional view illustrating an example semiconductor device 400 in accordance with various aspects of the present disclosure is shown. The example semiconductor device 400 may, for example, share any or all characteristics with the other example semiconductor devices presented herein (e.g., the example semiconductor device 100 of FIGS. 1-3, the example semiconductor devices 700 and 800 of FIGS. 7-12, etc.) As shown in FIG. 4, the example semiconductor device 400 comprises a composite plate 110 (e.g., a composite thin plate), a stress relieving layer 120 (e.g., a stress relieving film) on the composite plate 110, a semiconductor die 130 on the stress relieving layer 120, an insulation layer 140 covering the semiconductor die 130 and/or the stress relieving layer 120, a conductive layer 150 (which may also be referred to herein as a rewiring layer or redistribution layer, or a portion thereof) electrically connected to the semiconductor die 130, a dielectric layer 161 on the conductive layer 150, an interconnection structure 160 electrically coupled to the conductive layer 150, and a conductive via 470 that extends completely through at least the insulation layer 140 to electrically connect the conductive layer 150 and the composite plate 110 (e.g., the metal pattern 111 thereof).

In an example implementation, the composite plate 110, the stress relieving layer 120, the semiconductor die 130, the insulation layer 140, the conductive layer 150, the interconnection structure 160, and the dielectric layer 161 in the semiconductor device 400 are identical to those in the semiconductor device 100 shown in FIGS. 1-3. Thus, the following discussion will focus mainly on the conductive via 470 of the example semiconductor device 400 that is not shown and discussed with regard to the example semiconductor device 100.

The example conductive via 470 extends completely through the insulation layer 140 and the stress relieving layer 120 to electrically connect the metal pattern 111 of the composite plate 110 and the conductive layer 150. For example, a first via hole 442 extends completely through the insulation layer 140, and a second via hole 421 extends completely through the stress relieving layer 120. The via holes 442 and 421 may be filled (e.g., completely filled, partially filled for example covering inner surfaces of the via holes, etc.) with conductive material (e.g., metal, conductive paste, etc.). Note that via holes may similarly extend through the conductive layer 150 and/or metal pattern 111 as necessary. The conductive via 470 thus extends completely through the insulation layer 140 and the stress relieving layer 120 to electrically connect the conductive layer 150 formed on the first surface 140a of the insulation layer 140 and the metal pattern 111 of the composite plate 110. For example, the interconnection structure 160 formed on the conductive layer 150 may be electrically connected to the metal pattern 111 of the composite plate 110 by the conductive via 470. Similarly, a conductive pad 132 of the semiconductor device 130 may be electrically connected to the metal pattern 111.

With such a configuration, even when a plurality of such semiconductor devices 400 are stacked, an upper semiconductor device and a lower semiconductor device may be physically and electrically coupled to each other through the conductive via 470 (or a plurality thereof).

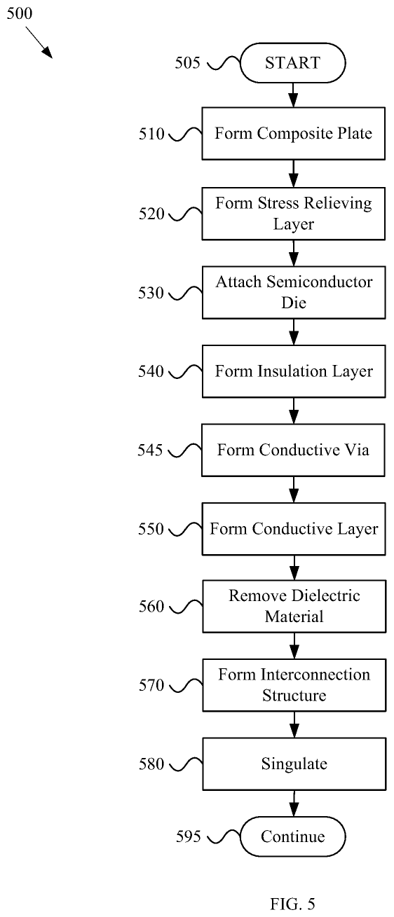

Referring to FIG. 5, a flow diagram illustrating an example method 500 of manufacturing the example semiconductor device 400 of FIG. 4 is shown. The example manufacturing method 500 may, for example, share any or all characteristics with the other example methods presented herein (e.g., the method 200, method 900, method 1100, etc.).

As shown in FIG. 5, the example manufacturing method 500 may comprise forming a composite plate at block 510, forming a stress relieving layer at block 520, attaching a semiconductor die at block 530, forming an insulation layer at block 540, forming a conductive via at block 545, forming a conductive layer at block 550, removing dielectric material at block 560, forming an interconnection structure at block 570, singulating at block 580, and continuing processing at block 595.

The forming of the composite plate at block 510, the forming of the stress relieving layer at block 520, the attaching of the semiconductor die at block 530, the forming of the insulation layer at block 540, the forming of the conductive layer at block 550, the removing of the dielectric material at block 560, the forming of the interconnection structure at block 570, the singulating at block 580, and the continued processing at block 595 may, for example, share any or all characteristics with corresponding blocks of the example method 200 shown in FIGS. 2-3 and discussed herein. For example, such corresponding blocks may be identical. Thus, the following discussion will focus mainly on the forming of the conductive via at block 545.

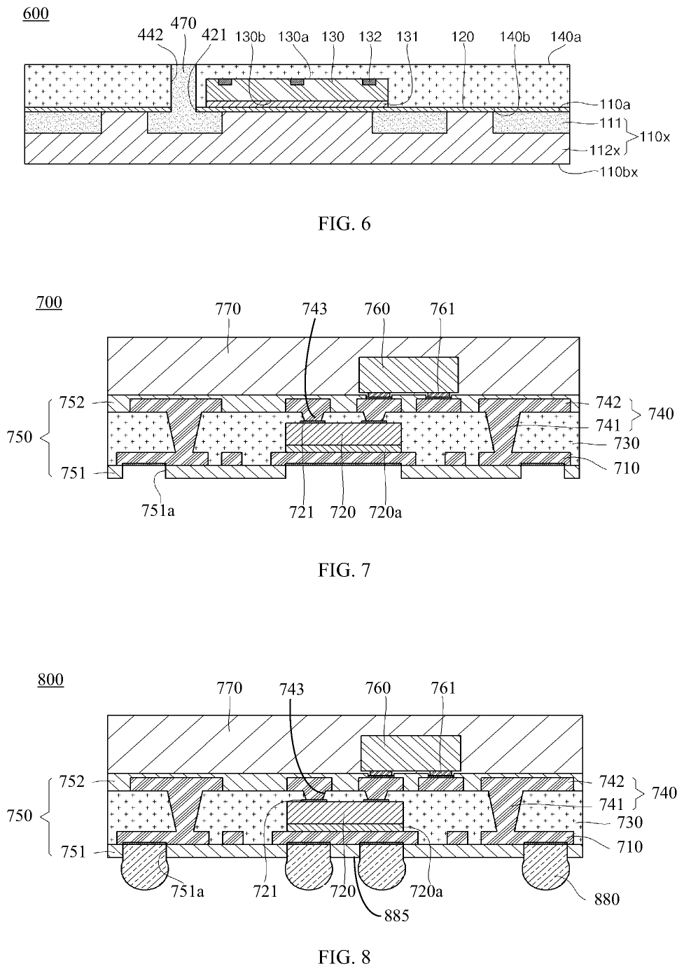

Referring to FIG. 6, a cross-sectional view illustrating the forming of the conductive via at block 545 is shown. During the forming of the conductive via at block 545, via holes 442 and 421 are formed extending completely through the insulation layer 140 and the stress relieving layer 120, respectively. Note that in an example implementation in which the stress relieving layer 120 does not extend to the conductive via 470, such a via hole through the stress relieving layer 120 is not necessary. A conductive via 470 may then be formed by filling the via holes 442 and 421 (e.g., completely filling, partially filling for example by covering inner surfaces of the via holes, etc.) with conductive material (e.g., metal, conductive paste, etc.). The via holes 442 and 421 may be formed such that the metal pattern 111 of the composite plate 110 (e.g., a portion thereof) is exposed to the outside by the via holes 442 and 421. The conductive material utilized to form the conductive via 470 may fill the via holes 442 and 421 and contact the exposed metal pattern 111 to create an electrical connection therewith that extends through the via holes 442 and 421.

FIG. 7 is a cross-sectional view illustrating an example semiconductor device 700 in accordance with various aspects of the present disclosure. The example semiconductor device 700 may, for example, share any or all characteristics with the other example semiconductor devices presented herein (e.g., the example semiconductor device 100 of FIGS. 1-3, the example semiconductor device 400 of FIGS. 4-6, the example semiconductor device 800 of FIGS. 8-12, etc.).

Referring to FIG. 7, the example semiconductor device 700 comprises a first conductive layer 710, a semiconductor die 720 on (or over) the first conductive layer 710, an insulation layer 730 on an upper surface and side surfaces of the first conductive layer 710 and surrounding the semiconductor die 720, a second conductive layer 742 on the insulation layer 730, a conductive via 741 extending through the insulation layer 730 between the first conductive layer 710 and the second conductive layer 742, a first dielectric layer 751 on the first conductive layer 710 and comprising vias (or apertures) exposing the first conductive layer 710, a second dielectric layer 752 on the second conductive layer 742 and comprising vias (or apertures) exposing the second conductive layer 752, and an electronic component 760 coupled to the second conductive layer 742 and/or the second dielectric layer 752. Additionally, an encapsulant 770 may surround the electronic component 760 and cover at least a top surface of the second dielectric layer 752.

The first conductive layer 710 may, for example, comprise a pattern (e.g., a contact pattern, land pattern, bond pad pattern, etc.), for example a standardized pattern, that supports connection of the semiconductor device 700 to an external circuit. The first conductive layer 710 may, for example, comprise one or more layers of any of a variety of materials (e.g., Cu, Au, Ag, Ni, Al, Ti, Cr, NiV, CrCu, TiW, TiN, alloys thereof, etc.).

In an example implementation, a land structure for connecting the first conductive layer 710 to an external component (e.g., to another semiconductor device, to a packaging substrate of a multi-device module, to a mother board, etc.) through an area of the first conductive layer 710 exposed to such external component may be formed. For example, in an example implementation, only a partial area of the first conductive layer 710 (e.g., corresponding to lands) is exposed from the bottom surface of the device 700 through apertures in the first dielectric layer 751. The exposed area may, for example, be connected to the external component utilizing any of a variety of interconnection structures (e.g., conductive bumps or balls, solder bumps or balls, copper or metal pillars or posts, etc.).

In an example fan-out configuration, a land structure may comprise a structure extending in a horizontal (or lateral) direction beyond the horizontal dimensions of the semiconductor die 720. Accordingly, the first conductive layer 710 may provide an extended input/output terminal structure in comparison to the conductive pads 721 of the semiconductor die 720.

The semiconductor die 720 is attached to an upper side of a pad (e.g., one or more pads) of the first conductive layer 710. The semiconductor die 720 may be attached in any of a variety of manners. In the example implementation shown in FIG. 7, the die 720 is attached to a pad of the first conductive layer 710 utilizing an adhesive member 720a (e.g., a die attach film, adhesive paste or liquid, etc.). In such an example implementation, heat generated by the semiconductor die 720 may be transferred to the outside of the device 700 through the pad of the first conductive layer 710 to which the semiconductor die 720 is attached. For example, the pad of the first conductive layer 710 to which the semiconductor die 720 is attached may serve as a heat dissipation pad. To assist with heat transfer, the adhesive member 720a may comprise a heat conductive material. Such material may also be, but need not be, electrically conductive. For example, in an example implementation, the semiconductor die 720 may be electrically connected (e.g., grounded, etc.) to the pad of the first conductive layer 710 via the adhesive member 720a. For example, though not shown, a ground connection may be formed between the pad and one or more conductive pads of the semiconductor die 720.

The example semiconductor die 720 comprises a plurality of conductive pads (e.g., bond pads, lands, etc.), one of which is shown at label 721, at one surface (e.g., a top surface) of the die 720. The conductive pad(s) 721 may also be referred to herein as contact pad(s) 721. The semiconductor die 720 shown in FIG. 7, for example, is positioned such that the conductive pad 721 faces upward, and the conductive pad 721 is electrically connected to the second conductive layer 742. The conductive pad 721 may, for example be connected to the second conductive layer 742 through an aperture in the insulation layer 730. The second conductive layer 742, or any part thereof, may be electrically connected to the first conductive layer 710. The conductive pad 721 may thus be electrically connected to the first conductive layer 710 and to an interconnection structure (e.g., a conductive bump, etc.) attached thereto.

Also for example, the conductive pad 721 (or another conductive pad of the semiconductor die 720) may be electrically connected to the electronic component 760, which in turn is also connected to the first conductive layer 710, and thus the semiconductor conductive pad 721 may be electrically connected to the first conductive layer 710 through the electronic component 760. As discussed herein, when the electronic component 760 is three-dimensionally mounted on (or over) and coupled to a position close to the conductive pad 721 of the semiconductor die 720, an electrical connection path length between the semiconductor die 720 and the electronic component 760 may be reduced, for example resulting in decreased path resistance, capacitance, signal delay, noise susceptibility, etc.

The insulation layer 730 is on the upper side of the first conductive layer 710 and covers the semiconductor die 720 (e.g., at least a top surface and lateral side surfaces thereof). The insulation layer 730 may, for example, comprise a Build-up Film (BF) (e.g., a resin layer, prepreg layer (e.g., an epoxy-impregnated fiber matrix, etc.), epoxy layer, dry film, etc.). The insulation layer 730 may comprise any one or more of a variety of materials (e.g., BF, a polymer, a polymer composite material (such as epoxy resin with filler, epoxy acrylate with filler, or polymer with proper filler), polyimide (PI), benzo cyclo butene (BCB), poly benz oxazole (PBO), bismaleimide triazine (BT), and phenolic resin, etc.), but the scope of this disclosure is not limited thereto.

The second conductive layer 742 is on the upper side of the insulation layer 730 and is electrically connected to the first conductive layer 710 and/or the semiconductor die 720 through one or more conductive vias. For example, the conductive via 741 electrically connects the second conductive layer 742 and the first conductive layer 710. Also for example, the conductive via 743 in the insulation layer 730 electrically connects the second conductive layer 742 to the conductive pad 721.

As discussed herein, the conductive via 741 (or conductive via 743) may be formed by forming a via hole from the top surface of the insulation layer 730 utilizing any of a variety of techniques (e.g., laser ablation, etc.). The via hole may then be filled (fully or partially) with a conductive material such as copper (e.g., utilizing a plating technique). Since the conductive via 741 (or conductive via 743) contacts a partial area of the first conductive layer 710 (or contacts the conductive pad 721 of the semiconductor die 720), such via forms an electrical path between the second conductive layer 742 and the first conductive layer 710 (or the conductive pad 721).

The second conductive layer 742 is formed with a pattern extending along at least a top side of the insulation layer 730. The second conductive layer 742 may, for example, be integrally formed with the conductive via 741 at the same time.

The dielectric layers 750 may, for example, comprise a first dielectric layer 751 formed on the bottom surface of the first conductive layer 710 and on a bottom surface of the insulation layer 730, and a second dielectric layer 752 formed on the top surface of the second conductive layer 742 and on a top surface of the insulation layer 730. The dielectric layers 750 may, for example, comprise a solder mask material. The dielectric layer 750 may, for example, comprise one or more of any of a variety of materials (e.g., solder resist, polymer resin, insulating resin, polyimide (PI), benzo cyclo butane (BCB), poly benz oxazole (PBO), bismaleimide triazine (BT), a phenolic resin, epoxy, etc.), but the scope of this disclosure is not limited thereto.

The first dielectric layer 751 may, for example, cover (or surround) the first conductive layer 710 but also comprise apertures 751a to expose a portion thereof, for example to form a land structure on the first conductive layer 710.

Additionally for example, the second dielectric layer 752 may cover (or surround) the second conductive layer 742 but also comprise apertures to expose a portion thereof, for example to provide a path through which the second conductive layer 742 is connected to the electronic component 760 and/or other components.

A land configuration or an interconnection structure configuration for board mounting (or for mounting to another device) may be provided on the first conductive layer 710 and/or on the second conductive layer 742. In an example implementation in which a land (or interconnection structure) configuration is provided on the second conductive layer 742 and/or on a portion of the first conductive layer 710, the first conductive layer 710 may serve as a shielding layer for the semiconductor device 700 (e.g., as discussed herein with regard to the metal pattern 111, etc.). Similarly, in an example implementation in which a land (or conductive bump) configuration is provided on the first conductive layer 710 and/or on a portion of the second conductive layer 742, the second conductive layer 742 may serve as a shielding layer for the semiconductor device 700 (e.g., as discussed herein with regard to the metal pattern 111, etc. As discussed herein (e.g., with regard to the semiconductor devices shown in FIGS. 1-6, etc.), such a shielding layer may be complete or may selectively comprise unshielded portions via which desirable electromagnetic waves may propagate.

The electronic component 760 may comprise any of a variety of different types of electronic components (e.g., an active component, a passive component (e.g., an integrated passive device (IPD)), a surface-mount component, etc.). The electronic component 760 may be configured to perform any of a variety of functions of the semiconductor device 700. Though FIG. 7 only shows a configuration in which the electronic component 760 is positioned on the upper surface of the insulation layer 730, the electronic component 760 (or other such electronic components) may be positioned inside the insulation layer 730 (e.g., alongside the semiconductor device 720). In an example implementation in which the electronic component 760 is configured with an IPD, the thickness of the electronic component 760 may be less than about 50 μm. In such an implementation, even if the electronic component 760 is positioned inside the insulation layer 730, such positioning might not increase the thickness of the semiconductor device 700 appreciably.

The electronic component 760 is electrically connected to the conductive layer 742 through one or more terminals, one of which is shown at label 761. Accordingly, the electronic component 760 may be electrically connected to the semiconductor die 720, to another electrical component of the semiconductor device 700, and/or to a circuit external to the semiconductor device 700. Additionally, since the terminal 761 of the component 760 is positioned close to the conductive pad 721 of the semiconductor die 720 (e.g., in a three-dimensional configuration), an electrical connection path length between the electronic component 760 and the semiconductor die 720 may be reduced, for example resulting in decreased path resistance, capacitance, signal delay, noise susceptibility, etc.

In the example shown, at least a first connection terminal of the electronic component 760 is positioned directly above the semiconductor die 720. Such connection terminal may also, for example, be positioned directly above the conductive pad 721 of the semiconductor die 720 to which it is connected. Also for example, the entire electronic component 760 may be positioned directly above the semiconductor die 720 or only a portion of the electronic component 760 might be positioned directly above the semiconductor die 720.

The encapsulant 770 may, for example, surround the component 760 (e.g., covering side surfaces thereof, covering a top surface thereof, underfilling and covering a bottom surface thereof, etc.) and cover the upper surface of the second dielectric layer 752. The encapsulant 770 may, for example, protect the semiconductor device 700 or any component thereof from an external environment. However, in an alternative implementation, the encapsulant 770 may expose the top surface of the component 760 (e.g., for heat dissipation, for other connections to be made thereto, etc.) and/or any other surface of the component 760.

FIG. 8 is a cross-sectional view illustrating an example semiconductor device in accordance with various aspects of the present disclosure. The example semiconductor device 800 may, for example, share any or all characteristics with the other example semiconductor devices presented herein (e.g., the example semiconductor device 700 of FIG. 7, the example semiconductor device 100 of FIGS. 1-3, the example semiconductor device 400 of FIGS. 4-6, etc.).

Referring to FIG. 8, the example semiconductor device 800 comprises a first conductive layer 710, a semiconductor die 720 on (or over) the first conductive layer 710, an insulation layer 730 on an upper surface and side surfaces of the first conductive layer 710 and surrounding the semiconductor die 730, a second conductive layer 742 on the insulation layer 730, a conductive via 741 extending through the insulation layer 730 between the first conductive layer 710 and the second conductive layer 742, a first dielectric layer 751 on the first conductive layer 710 and comprising vias (or apertures) exposing the first conductive layer 710, a second dielectric layer 752 on the second conductive layer 742 and comprising vias (or apertures) exposing the second conductive layer 752, an electronic component 760 coupled to the second conductive layer and/or to the second dielectric layer 752, an encapsulant 770 that surrounds the electronic component 760 and covers at least a top surface of the second dielectric layer 752, and an interconnection structure 880 on the first conductive layer 710 and extending through apertures 751a in the first dielectric layer 751. In FIG. 8, the same reference numbers as utilized in FIG. 7 are assigned to like parts. The discussion of FIG. 8 will thus focus mainly on differences between the example semiconductor device 700 of FIG. 7 and the example semiconductor device 800 of FIG. 8.

An exposed land area of the first conductive layer 710 may, for example, be exposed through a respective aperture 751a (or via) in the first dielectric layer 751. The interconnection structure 880 is coupled to the exposed land area of the first conductive layer 710 through the aperture 751a. The interconnection structure 880 may comprise any of a variety of types of interconnection structures. For example, the interconnection structure 880 may share any or all characteristics with the interconnection structure 160 discussed herein. For example, the interconnection structure 880 may comprise a package interconnection structure by which the semiconductor device 800 may be electrically and/or mechanically connected to another device, substrate of a multi-device module, mother board, etc.

As with any other interconnection structure discussed herein, prior to formation (or attachment) of the interconnection structure 880, an Under Bump Metallization (UBM) structure may (but not necessarily) be formed on the exposed land to enhance the coupling between the interconnection structure 880 and the exposed land. For example, a UBM structure may comprise a layer of titanium-tungsten (TiW), which may be referred to as a layer or seed layer. Such layer may, for example be formed by sputtering. Also for example, the UBM structure may comprise a layer of copper (Cu) on the layer of TiW. Such layer may also, for example, be formed by sputtering. Note however, that the UBM structure and/or processes utilized to form the UBM structure are not limited to the examples given.

The interconnection structure 880 may comprise any of a variety of different types of interconnection structures (e.g., conductive ball, solder ball, conductive bump, solder bump, metal post, etc.), which may comprise any one or more of a variety of materials (e.g., Sn, Pb, Cu, Au, Ag, Ni, Al, Ti, Cr, NiV, CrCu, TiW, TiN, alloys thereof, etc.). The scope of this disclosure is not, however, limited by characteristics of any particular interconnection structure material or process.

As shown in FIG. 8, a plurality of the interconnection structures 880 may be connected to the portion (e.g., a pad, plurality of traces, etc.) of the first conductive layer 710 to which the semiconductor die 721 is attached.

The interconnection structure(s) 880 may, for example, be utilized to electrically and mechanically couple the example semiconductor device 800 with an external circuit (e.g., another device, a multi-device module substrate, a mother board, etc.).

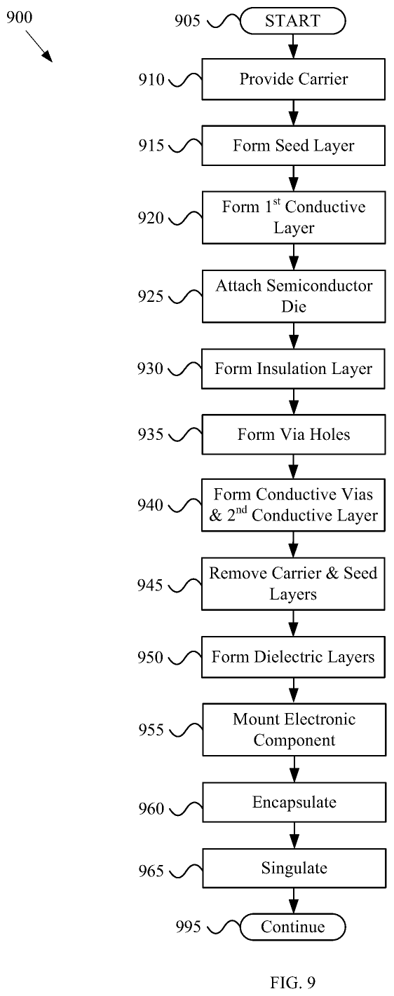

Referring to FIG. 9, such figure shows a flow diagram illustrating an example method 900 of manufacturing the semiconductor device 700 of FIG. 7 and/or the semiconductor device 800 of FIG. 8. The example method 900 may, for example, share any or all characteristics with the other example methods presented herein (e.g., the method 200, method 500, method 1100, etc.).

As shown in FIG. 9, the example manufacturing method 900 may comprise providing a carrier at block 910, forming seed layer(s) at block 915, forming a first conductive layer at block 920, attaching a semiconductor die at block 925, forming an insulation layer at block 930, forming via hole(s) at block 935, forming conductive via(s) and a second conductive layer at block 940, removing the carrier and seed layer(s) at block 945, forming dielectric layer(s) at block 950, mounting an electronic component at block 955, encapsulating at block 960, singulating at block 965, and performing continued processing at block 995.

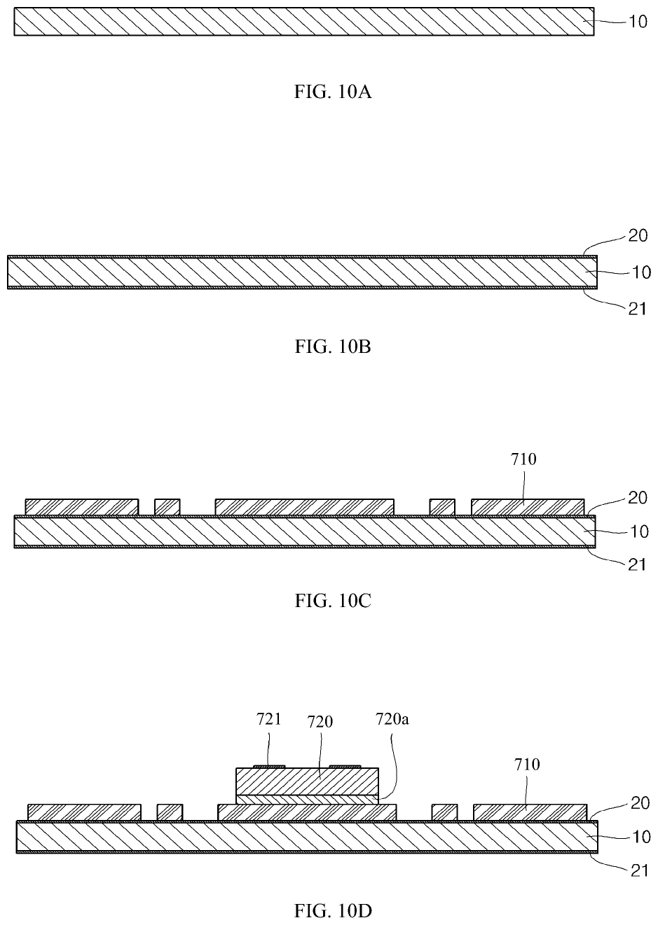

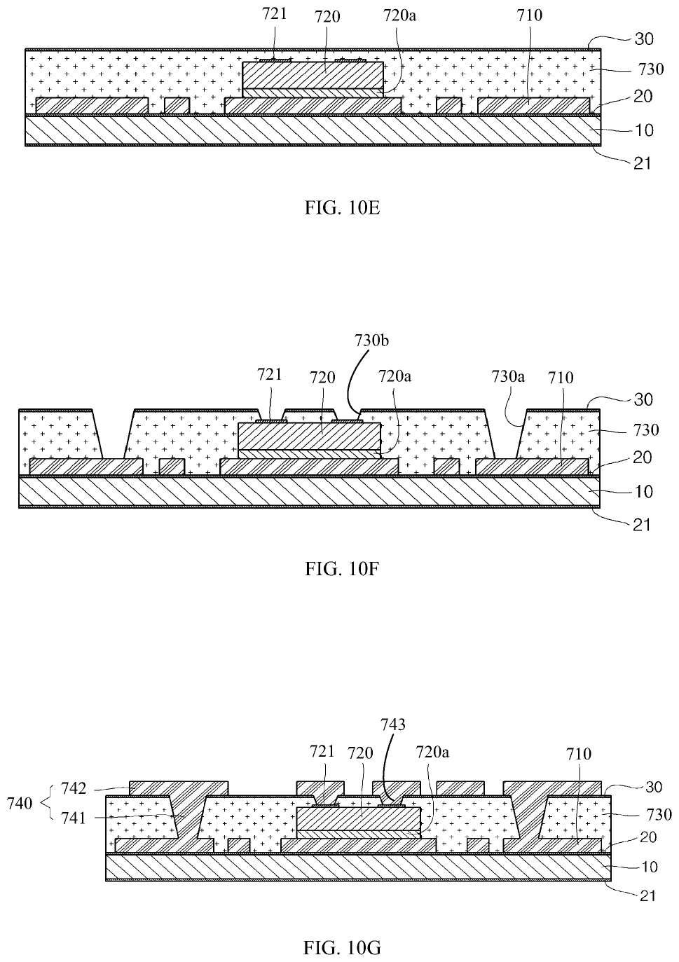

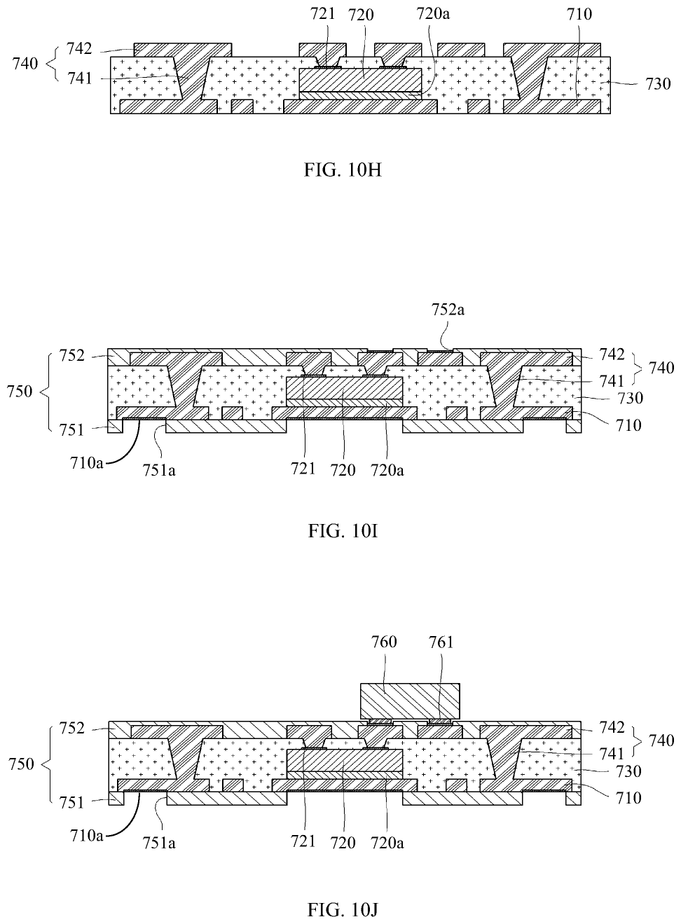

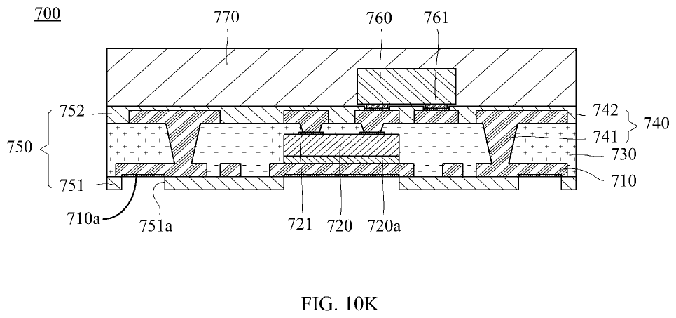

Referring to FIGS. 10A to 10K, such figures are cross-sectional views illustrating various aspects of the example method 900 shown in FIG. 9. The example method 900 of manufacturing shown in FIG. 9 will now be discussed with reference to FIGS. 10A-10K.

First, referring to FIG. 10A, a cross-sectional view illustrating the carrier providing of block 910 is shown. The carrier 10 may comprise any of a variety of materials. For example, the carrier 10 may comprise stainless steel. Also for example, the carrier 10 may comprise any one or more of a variety of materials (e.g., metals, glass, silicon, etc.). The carrier 10 may comprise any of a variety of shapes. For example, the carrier 10 may comprise a rectangular or square panel shape, a circular wafer shape, etc. The carrier 10 may comprise areas or regions on which respective semiconductor devices may be formed. Such areas or regions may, for example, be arranged in a two-dimensional array, a one-dimensional array, etc.

The carrier 10 may comprise any of a variety of dimensions. In an example implementation, the carrier 10 may comprise a thickness of about 50 μm to about 300 μm. For example, depending on the material composition of the carrier 10, a thickness of 50 μm or more may provide rigid support for manufacturing processes, while a thickness of 300 μm or less may provide for enhanced handling and removability of the carrier 10.

Referring to FIG. 10B a cross-sectional view illustrating the seed layer forming of block 915 is shown. For example, seed layers 20 and 21 may be respectively formed on the top and bottom surfaces of the carrier 10. The seed layers 20 and 21 may comprise any of a variety of materials. For example, the seed layers 20 and 21 may comprise copper. Also for example, the seed layers 20 and 21 may comprise one or more layers of any of a variety of metals (e.g., copper, silver, gold, aluminum, tungsten, titanium, nickel, molybdenum, alloys thereof, etc.). The seed layers may be formed utilizing any of a variety of techniques (e.g., sputtering or physical vapor deposition (PVD), chemical vapor deposition (CVD), electroless plating, electrolytic plating, etc.). The seed layers 20 and 21 may, for example, be utilized during a subsequent electroplating process. Though the illustrations in FIGS. 10A-10K show multiple seed layers 20 and 21 formed on a top side and bottom side of the carrier 10, respectively, both seed layers need not be formed. For example, in another example implementation, block 915 may comprise forming only the top seed layer 20.

Referring to FIG. 10C, a cross-sectional view illustrating the first conductive layer forming of block 920 is shown. For example, a first conductive layer 710 is formed on the top surface of the seed layer 20 (e.g., directly on the top surface of the seed layer 20). The first conductive layer 710 may, for example, be formed of the same material as the seed layer 20, but need not be. The first conductive layer 710 may be formed in any of a variety of manners. For example, the first conductive layer 710 may be formed by masking the seed layer 20 (e.g., with a patterned dry film, patterned dielectric material, etc.) at locations at which the first conductive layer 710 is not desired, electroplating the first conductive layer 710 on the portions of the seed layer 20 that are exposed through the mask, and then removing the mask (e.g., utilizing a mechanical and/or chemical removing or stipping technique).

Referring to FIG. 10D, a cross-sectional view illustrating the semiconductor die attaching of block 925 is shown. For example, the semiconductor die 720 is attached on the upper side of the first conductive layer 710. The semiconductor die 720 may be attached in any of a variety of manners. For example, in an example implementation, the semiconductor die 720 may be attached to an attachment area of the first conductive layer 710 utilizing an adhesive member 720a positioned between the semiconductor die 720 and the attachment area of the first conductive layer 710. The adhesive member 720a may comprise any of a variety of characteristics. For example, the adhesive member 720a may comprise a die attach film, a layer of adhesive paste or liquid, etc. The adhesive member 720a may, for example, comprise a heat conductive material. Such material may also be, but need not be, electrically conductive. For example, in an example implementation, the semiconductor die 720 may be electrically connected (e.g., grounded, etc.) to the attachment area (or pad) of the first conductive layer 710 via the adhesive member 720a. For example, the bottom side of the semiconductor die 720 may be electrically coupled to a conductive pad 721 on the top side of the die 720.

In an example implementation, top side (or surface) of the semiconductor die 720 may, for example, comprise an active surface (or front side) of the die 720, and the bottom surface (or side) of the semiconductor die 720 may comprise an inactive surface (or back side) of the die 720. As discussed herein, the plurality of conductive pads 721 of the semiconductor die 720 may, for example, be electrically connected to the first conductive layer 710 through via holes in the insulation layer 730.

Referring to FIG. 10E, a cross-sectional view illustrating the insulation forming of block 930 is shown. For example, an insulation layer 730 may be formed on the upper side of the first conductive layer 710 to surround the semiconductor die 720 (e.g., covering a top surface and/or side surfaces of the die 720). The insulation layer 730 may also, for example cover upper side and/or lateral side surfaces of the first conductive layer 710.

The insulation layer 730 may comprise any of a variety of materials. The insulation layer 730 may, for example, comprise a Build-up Film (BF) (e.g., a resin layer, prepreg layer (e.g., an epoxy-impregnated fiber matrix, etc.), epoxy layer, dry film, etc.). The insulation layer 730 may comprise any one or more of a variety of materials (e.g., BF, a polymer, a polymer composite material (such as epoxy resin with filler, epoxy acrylate with filler, or polymer with a proper filler), polyimide (PI), benzo cyclo butene (BCB), poly benz oxazole (PBO), bismaleimide triazine (BT), and phenolic resin, etc.), but the scope of this disclosure is not limited thereto. The insulation layer 730 may, for example, comprise a thickness that is greater than a thickness of the semiconductor die 720. In an alternative configuration however, a top side of the semiconductor die 720 may be exposed from the insulation layer 730 (e.g., the top side of the die 720 may be coplanar with the top side of the insulation layer 730). The insulation layer 730 may be formed in any of a variety of manners (e.g., vacuum lamination and/or hot-pressing, compression molding, transfer molding, liquid encapsulant molding, paste printing, film assisted molding, flooding, curing, etc.).

Additionally, an upper seed layer 30 may be formed on the top surface of the insulation layer 730. The upper seed layer 30 may, for example, comprise any or all characteristics of the first seed layer 20 and/or the second seed layer 21 discussed herein. For example, the upper seed layer 30 may comprise copper (e.g., a plated copper layer or foil). Also for example, the upper seed layer 30 may comprise one or more layers of any of a variety of metals (e.g., copper, silver, gold, aluminum, tungsten, titanium, nickel, molybdenum, alloys thereof, etc.).

The upper seed layer 30 may be formed utilizing a same type of process as utilized for the formation of the first seed layer 20 and/or the second seed layer 21, but the scope of this disclosure is not limited thereto. For example, the upper seed layer 30 may be formed utilizing any of a variety of techniques (e.g., sputtering or physical vapor deposition (PVD) technique, chemical vapor deposition (CVD), electroless plating, electrolytic plating, etc.). The upper seed layer 30 may, for example, be used as a seed layer for forming a second conductive layer 740 (or a portion thereof).

The upper seed layer 30 (or any seed layer discussed herein) may comprise any of a variety of dimensions. For example, in an example implementation, the upper seed layer 30 may comprise a thickness of less than about 2 μm. As discussed herein, at least a portion of the upper seed layer 30 may be removed during a later operation. A thickness of less than about 2 μm may, for example, provide for efficient removal.

Referring to FIG. 10F, a cross-sectional view illustrating the via forming of block 935 is shown. For example, a via hole 730a may be formed from the upper surface of the upper seed layer 30 and/or the insulation layer 730 and passing through the upper seed layer 30 and the insulation layer 730 to the first conductive layer 710. Additionally, a via hole 730b may be formed from the upper surface of the upper seed layer 30 and/or the insulation layer 730 and passing through the upper seed layer 30 and the insulation layer 730 to a conductive pad 721 of the semiconductor die 720. The via hole(s) 730a and 730b may be formed utilizing any of a variety of techniques (e.g., laser ablation, mechanical drilling or ablation, chemical ablation, etc.). After forming the via holes 730a and 730b, a process for cleaning the via holes 730a and 730b may also be performed. Note that any number of such example vias may be formed.

Referring to FIG. 10G, a cross-sectional view illustrating the conductive via and second conductive layer forming of block 940 is shown. For example, to form the conductive via(s) 741 and 743, conductive material may be formed in the vias formed at block 935 (e.g., in one or more vias 730a extending through the upper seed layer 30 and insulation layer 730 from the top of the upper seed layer 30 and/or insulation layer 730 to the first conductive layer 710, in one or more vias 730b extending through the upper seed layer 30 and insulation layer 730 from the top of the upper seed layer 30 and/or insulation layer 730 to a conductive pad 721 of the semiconductor die 720, etc.). Such conductive material may be formed in the vias 730a and 730b in any of a variety of manners. For example, the conductive material may comprise a paste that is deposited in the vias 730a and 730b by printing, injecting, etc. Also for example, the conductive material may comprise metal (e.g., copper, silver, gold, aluminum, tungsten, titanium, nickel, molybdenum, alloys thereof, etc.) that is plated in the vias 730a and 730b (e.g., filling the vias entirely, covering side surfaces of the vias while not completely filling the vias, etc.).

The second conductive layer 742 may be formed on the top surface of the insulation layer 730. In an example implementation, the second conductive layer 742 may be formed in a same process (e.g., a same plating process, etc.) as the conductive vias 741. In an alternative implementation, the second conductive layer 742 may be formed in a process that is different from the conductive via forming. Though the second conductive layer 742 is shown as a single conductive layer, it should be understood that the second conductive layer 742 may comprise a multi-layer structure comprising a plurality of conductive layers and one or more dielectric layers between adjacent conductive layers.

Note that in various example implementations, the forming of the top seed layer 30 (e.g., discussed with regard to block 930) may be performed after the via forming (e.g., discussed with regard to block 935). Such order of operations may, for example, result in the top seed layer 30 being formed on inner side surfaces of the vias 730a and 730b formed in the insulation layer 730 and on a top surface of the insulation layer 730.

Referring to FIG. 10H, a cross-sectional view illustrating the carrier and seed layer removing of block 945 is shown. The carrier 10 may be removed in any of a variety of manners. For example, the carrier 10 may be removed by mechanical peeling, shearing, grinding, etc. The carrier 10 may also, for example, be removed by chemical etching, etc.

The seed layer removing may be performed in any of a variety of manners. For example, in an example scenario in which the first seed layer 20 remains after removal of the carrier 10, the first seed layer 20 may be etched. Such etching may, for example, expose a bottom surface of the first conductive layer 710 formed on the first seed layer 20 and a bottom surface of the insulation layer 730 formed on the first seed layer 20. Removal of the upper seed layer 30 may, for example, expose a top surface of the insulation layer 730 on which the upper seed layer 30 was formed. Although not illustrated in FIG. 10H, remnants of the upper seed layer 30 may remain after etching. For example, portions of the upper seed layer 30 that are covered by the second conductive layer 742 and/or portions of the upper seed layer 30 (if present) that are covered by the conductive material in the conductive vias 741 may remain. Note that chemical etching utilized to remove the seed layers may partially etch the first conductive layer 710 and/or the second conductive layer 742, but such etching is minimal.

Referring to FIG. 10I, a cross-sectional view illustrating the dielectric layer forming of block 950 is shown. Such forming of the dielectric layers 750 may, for example, comprise forming a first dielectric layer 751 on the bottom surface of the first conductive layer 710 and on a bottom surface of the insulation layer 730, and forming a second dielectric layer 751 on the top surface of the second conductive layer 740 and on a top surface of the insulation layer 730. The dielectric layers 750 (which may also be referred to herein as passivation layers) may comprise any of a variety of materials. For example, the dielectric layers 750 may comprise a solder mask material. Also for example, the dielectric layers 750 may comprise one or more of any of a variety of materials (e.g., solder resist, polymer resin, insulating resin, polyimide (PI), benzo cyclo butane (BCB), poly benz oxazole (PBO), bismaleimide triazine (BT), a phenolic resin, epoxy, etc.), but the scope of this disclosure is not limited thereto. In various implementations, an inorganic dielectric may also be utilized (e.g., Si₃N₄, SiO₂, SiON, etc.). The dielectric layers 750 may be formed utilizing any of a variety of techniques. For example, the dielectric layers 750 may be formed using any one or more of a variety of dielectric deposition processes, for example printing, spin coating, spray coating, sintering, thermal oxidation, plasma vapor deposition (PVD), chemical vapor deposition (CVD), etc.

A land structure 710a of the first conductive layer 710 may be exposed through an opening 751a (or aperture) in the first dielectric layer 751. Similarly, a portion of the top surface of the second conductive layer 740 may be exposed through an opening 752a (or aperture) in the second dielectric layer 752. The openings 751a and 752a may be formed in any of a variety of manners (e.g., masking/etching, laser ablation, mechanical ablation, etc.).

In the example shown in FIG. 10I, a pad area of the first conductive layer 710 on which the semiconductor die 720 is mounted (or a portion thereof) may be exposed through an opening in the first dielectric layer 751. As discussed herein, such a pad area may be exposed for providing heat dissipation and/or for providing an electrical connection (e.g., a ground connection) to the semiconductor die 720 through the exposed pad area.

Referring to FIG. 10J, a cross-sectional view illustrating the electronic component mounting of block 955 is shown. The electronic component 760 may be mounted (or attached) in any of a variety of manners. For example, the component 760 may be mounted on the upper surface of the second dielectric layer 752. In an example implementation, a terminal 761 of the electronic component 760 may be electrically and mechanically connected (e.g., soldered, adhered, etc.) to a portion of the second conductive layer 742 that is exposed through the opening 752a in the second dielectric layer 752. Note that an underfill material may also be formed between a body of the electronic component 760 and the dielectric layer 752.

As mentioned herein, when an opening 752a in the second dielectric layer 752 is located close to the conductive pad 721 of the semiconductor die 720, the length of an electrical connection path between the semiconductor die 720 and the component 760 may be reduced so that the electrical performance of the semiconductor device 800 can be improved. In an example configuration, an opening 752a in the second dielectric layer 752 may be positioned directly above a conductive pad 721 of the semiconductor die 720. Such may be the case with a plurality of such openings 752a and respective bond pads 721.

Referring to FIG. 10K, a cross-sectional view illustrating the encapsulating of block 960 is shown. For example, an encapsulant 770 may be formed to surround the component 760 (e.g., partially or completely covering a top surface of the component 760, side surfaces of the component 760 and/or a bottom surface of the component 760). The encapsulant 770 may, for example, protect the component 760 and other encapsulated components from an external impact or environmental condition. In an example implementation, the top surface of the component 760 may be exposed through the encapsulant 770 (e.g., exposed through a hole or an aperture in the encapsulant 770, in a manner in which the top surface of the component 760 and a top surface of the encapsulant 770 are coplanar, etc.).

The encapsulant 770 may comprise any one or more of a variety of materials (e.g., BF, a polymer, a polymer composite material (such as epoxy resin with filler, epoxy acrylate with filler, or polymer with proper filler), polyimide (PI), benzo cyclo butene (BCB), poly benz oxazole (PBO), bismaleimide triazine (BT), and phenolic resin, etc.), but the scope of this disclosure is not limited thereto. The encapsulant 770 may be formed in any of a variety of manners (e.g., vacuum lamination and/or hot-pressing, compression molding, transfer molding, liquid encapsulant molding, paste printing, film assisted molding, flooding, etc.).

In the above manner, the example semiconductor device 700 shown in FIG. 7, in accordance with various aspects of the present disclosure, may be manufactured. Additionally, one or more interconnection structures 880, as shown in FIG. 8, may be added (e.g., coupled to one or more land structures of the first conductive layer 710 exposed through openings 751a in the first dielectric layer 751), thereby producing the example semiconductor device 800 shown in FIG. 8. In an example implementation, prior to formation of the interconnection structures 880, under bump metallization may be formed on the exposed land structure.

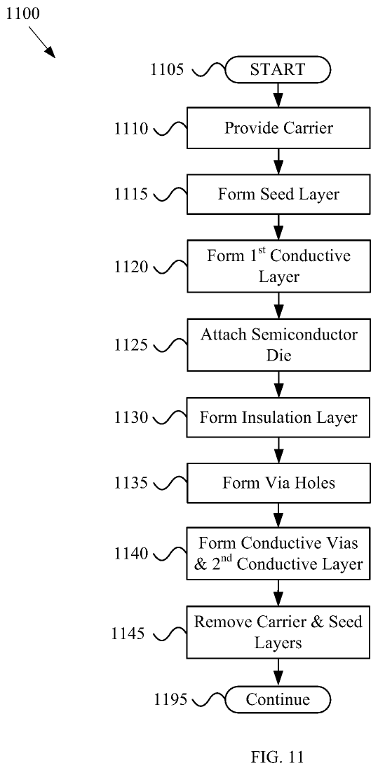

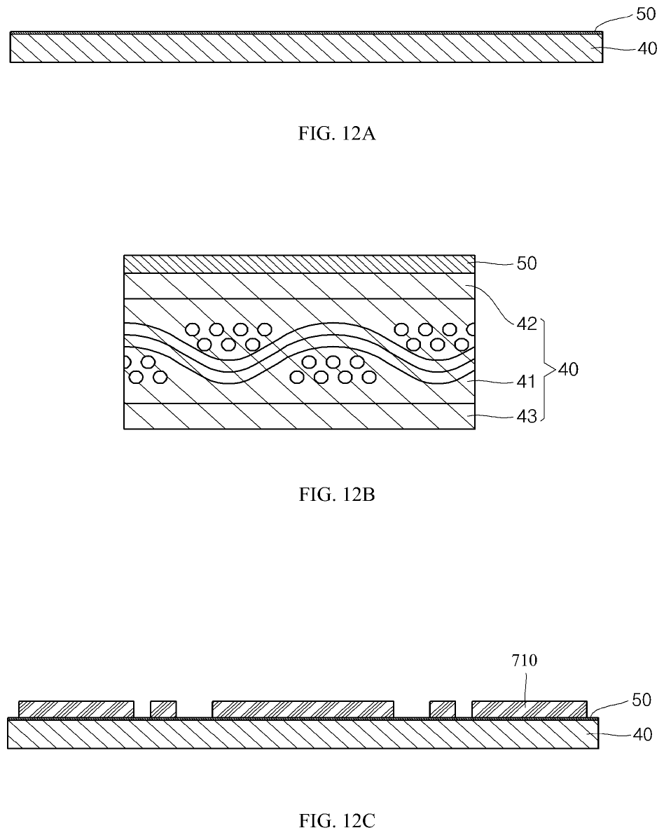

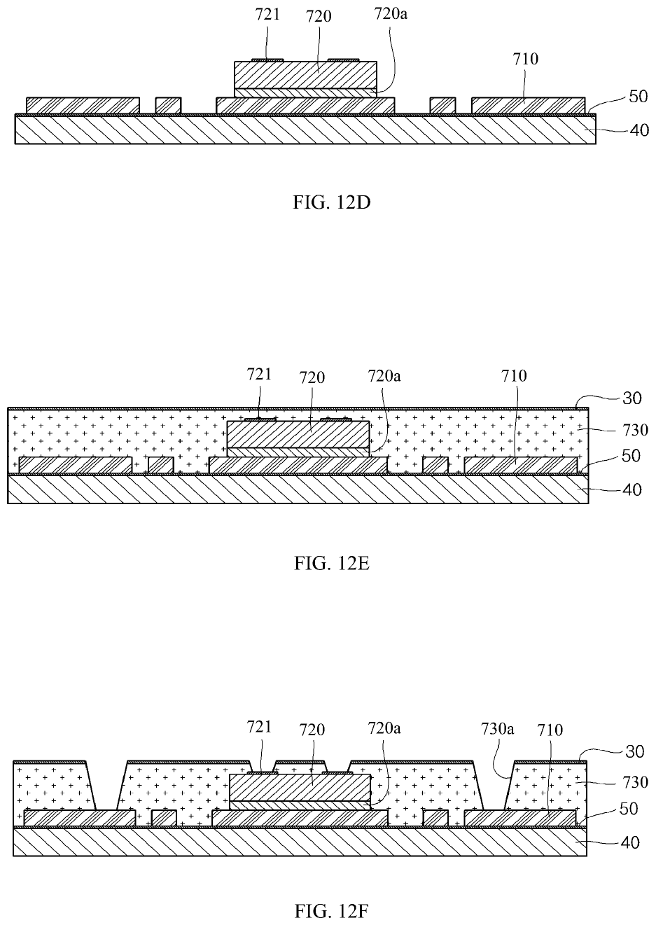

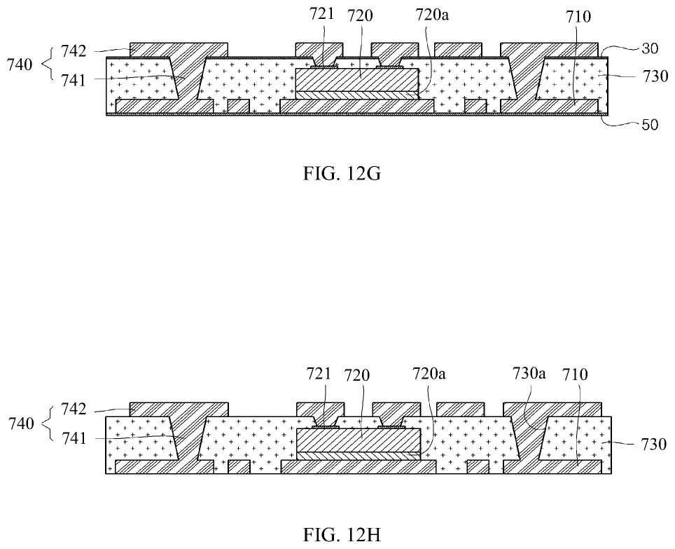

The discussion herein with regard to FIG. 9 and FIGS. 10A-10K presented an example method of manufacturing the semiconductor device 700 shown in FIG. 7 and/or the semiconductor device 800 shown in FIG. 8. The following discussion with regard to FIG. 11 and FIGS. 12A to 12H may, for example, provide another example method of manufacturing such devices.

Referring to FIG. 11, such figure shows a flow diagram illustrating an example method 1100 of manufacturing the semiconductor device 700 of FIG. 7 and/or the semiconductor device 800 of FIG. 8. The example method 1100 may, for example, share any or all characteristics with the other example methods presented herein (e.g., the method 200, method 500, method 900, etc.).

As shown in FIG. 11, the example manufacturing method 1100 may comprise providing a carrier at block 1110, forming a seed layer at block 1115, forming a first conductive layer at block 1120, attaching a semiconductor die at block 1125, forming an insulation layer at block 1130, forming via hole(s) at block 1135, forming conductive via(s) and a second conductive layer at block 1140, removing the carrier and seed layer(s) at block 1145, and performing continued processing at block 1195.

Referring to FIGS. 12A to 12H, such figures are cross-sectional views illustrating various aspects of the example method 1100 shown in FIG. 11. The example method 1100 of manufacturing in FIG. 11 will now be discussed with reference to FIGS. 12A-12H.

First, referring to FIGS. 12A and 12B, a cross-sectional view illustrating the carrier providing of block 1110 is shown. Block 1110 may, for example, share any or all characteristics with example block 910 of FIG. 9. The carrier 10 may comprise any of a variety of materials. For example, the carrier 40 may comprise a copper clad laminate (CCL) structure (e.g., as used in a printed circuit board (PCB), etc.). For example, the example carrier 40 is shown with an upper copper clad layer 42 on the top side of the insulation layer 41, and a lower copper clad layer 43 on the bottom side of the insulation layer 41. The insulation layer 41 may, for example, comprise a prepreg layer or other insulative material (e.g., polyimide, etc.), laminate, etc. Note that although only a single insulation layer 41 and two copper clad layers 42 and 43 are shown, the carrier 40 may comprise any number of such layers. The carrier 40 may, for example, share any or all characteristics with other carriers discussed herein.

Also referring to FIGS. 12A and 12B, a cross-sectional view illustrating the seed layer forming of block 1115 is shown. Block 1115 may, for example, share any or all characteristics with example block 915 of FIG. 9. In an example implementation, a copper (or other metal) foil 50 is attached to the upper side of the carrier 40 with an adhesive. The copper foil 50 may, for example, serve as a seed layer. Additionally, during the attaching of the copper foil 50, the adhesive might be applied only along the edge of the carrier 40 (or otherwise applied at selected locations, rather than over the entire surface of the carrier 40) to facilitate the later removal of the copper foil 50.

Referring to FIG. 12C, a cross-sectional view illustrating the first conductive layer forming of block 1120 is shown. Block 1120 may, for example, share any or all characteristics of the example block 920 of FIG. 9. For example, a first conductive layer 710 is formed on the top surface of the copper foil 50. In an example implementation, the first conductive layer 710 may be formed by masking the copper foil 50 (or other seed layer) (e.g., with a patterned dry film, patterned dielectric material, etc.) at locations at which the first conductive layer 710 is not desired, electroplating the first conductive layer 710 on the portions of the copper foil 50 that are exposed through the mask, and then removing the mask (e.g., utilizing a mechanical and/or chemical removing technique).

Referring to FIG. 12D, a cross-sectional view illustrating the semiconductor die attaching of block 1125 is shown. For example, block 1125 may share any or all characteristics with the example block 925 of FIG. 9. For example, the semiconductor die 720 may be attached to an area of the first conductive layer 710 utilizing an adhesive member 720a (e.g., die attach film, adhesive paste or liquid layer, etc.). The adhesive member 720a may, for example be thermally and/or electrically conductive.

Referring to FIG. 12E, a cross-sectional view illustrating the insulation forming of block 1130 is shown, Block 1130 may, for example, share any or all characteristics with example block 930 of FIG. 9. The insulation layer 730 may, for example, cover a top surface and/or side surfaces of the die 720. The insulation layer 730 may, for example, comprise a Build-up Film (BF) (e.g., a resin layer, prepreg layer (e.g., an epoxy-impregnated fiber matrix, etc.), epoxy layer, dry film, etc.). The insulation layer 730 may comprise any one or more of a variety of materials (e.g., BF, a polymer, a polymer composite material (such as epoxy resin with filler, epoxy acrylate with filler, or polymer with a proper filler), polyimide (PI), benzo cyclo butene (BCB), poly benz oxazole (PBO), bismaleimide triazine (BT), and phenolic resin, etc.), but the scope of this disclosure is not limited thereto. The insulation layer 730 may be formed in any of a variety of manners (e.g., vacuum lamination and/or hot-pressing, compression molding, transfer molding, liquid encapsulant molding, paste printing, film assisted molding, flooding, curing, etc.).

Additionally, as discussed herein with regard to block 930, an upper seed layer 30 may also be formed on the top surface of the insulation layer 730.

Referring to FIG. 12F, a cross-sectional view illustrating the via forming of block 1135 is shown. Block 1135 may, for example, share any or all characteristics with the example block 935 of FIG. 9.

Referring to FIG. 12G, a cross-sectional view illustrating the second conductive layer forming of block 1140 is shown. Block 1140 may, for example, share any or all characteristics with the example block 940 of FIG. 9.

Additionally, still referring to FIG. 12G, a cross-sectional view illustrating the carrier removing of block 1145 is shown. Block 1145 may, for example, share any or all characteristics with the example block 945 of FIG. 9. For example, in an example implementation discussed herein, the copper foil 50 was temporarily attached to the carrier 40 at block 1115. In such an example implementation, a notch (or gap) may be formed between the carrier and the copper foil 50, at which point the copper foil 50 may be peeled. In an example implementation, the copper foil 50 may have been attached to the carrier 40 at block 1115 utilizing a thermal release adhesive. In such an implementation, a temperature may be applied that is high enough to release the adhesive, at which point the copper foil 50 may be conveniently separated from the carrier 40.

Referring to FIG. 12H, a cross-sectional view illustrating the seed layer removing of block 1145 is shown. Block 1145 may, for example, share any or all characteristics with the example block 945 of FIG. 9. For example, in an example implementation in which copper foil 50 is attached to the carrier 40 as a seed layer at block 1115, the copper foil 50 may be removed by etching. In such case, the bottom surface of the first conductive layer 710 that was formed on the copper foil 50 will be exposed, along with the bottom surface of the insulation layer 730. Also for example, at least portions of the top seed layer 30 (e.g., as formed at block 1130) may be removed by etching. In such case, removal of the upper seed layer 30 may, for example, expose a top surface of the insulation layer 730 on which the upper seed layer 30 was formed. Although not illustrated in FIG. 12H, remnants of the upper seed layer 30 may remain after etching. For example, portions of the upper seed layer 30 that are covered by the conductive material in the conductive vias 741 may remain. Note that chemical etching utilized to remove the seed layers may partially etch the first conductive layer 710 and/or the second conductive layer 742, but such etching is minimal.

The example method 1100 may comprise performing continued processing at block 1195. Such continued processing may comprise any of a variety of characteristics. Block 1195 may, for example, share any or all characteristics with the example blocks 950, 955, 960, 965, and 995 of FIG. 9. For example, block 1195 may comprise performing the operations necessary to complete production of the example semiconductor devices 700 and 800 shown in FIGS. 7 and 8.

Various aspects of the present disclosure provide a semiconductor device, and a manufacturing method thereof, that selectively shields electromagnetic waves to and/or from the semiconductor device so that an antenna provided in the semiconductor device may be able to communicate effectively while undesirable electromagnetic waves are shielded.

Additionally, various aspects of the present disclosure provide a semiconductor device, and a manufacturing method thereof, that comprises a composite plate comprising a dielectric layer and a metal pattern (e.g., instead of a thick steel substrate) for shielding electromagnetic waves so that the thickness of the semiconductor device may be reduced. Component interconnections utilizing the metal pattern may also be provided.

Also, various aspects of the present disclosure provide a semiconductor device, and a manufacturing method thereof, that provides for selective shielding of electromagnetic waves and provides for semiconductor devices laminated in a stack that comprises conductive vias for interconnection between layers.

Further for example, various aspects of the present disclosure provide a semiconductor device, and a manufacturing method thereof, that provides for a reduced electrical path length between a built-in semiconductor die and an electrical component by utilizing a three-dimensional connection of a built-in semiconductor die and a component in which the component is three-dimensionally connected to a position close to the built-in semiconductor die using a conductive layer formed vertically between the semiconductor die and the component.

Also for example, various aspects of the present disclosure provide a semiconductor device, and a manufacturing method thereof, comprising a structure in which a built-in semiconductor die is seated on a heat dissipation pad and provides for selective shielding with a conductive layer.

Additionally for example, various aspects of the present disclosure provide a semiconductor device, and a manufacturing method thereof, that comprises a first conductive layer disposed in a first direction (e.g., a horizontal or lateral direction) and formed of metal, a semiconductor die seated on the upper side of the first conductive layer, an insulation layer formed to surround the semiconductor die, and a second conductive layer (or conductive via) penetrating the insulation layer in a second direction (e.g., a vertical direction) perpendicular to the first direction to that is electrically connected to at least one of the first conductive layer and the semiconductor die.

In summary, various aspects of this disclosure provide a selectively shielded and/or three-dimensional semiconductor device and a method of manufacturing thereof. For example and without limitation, various aspects of this disclosure provide a semiconductor device that comprises a composite plate for selective shielding and/or a three-dimensional embedded component configuration. While the foregoing has been described with reference to certain aspects and examples, it will be understood by those skilled in the art that various changes may be made and equivalents may be substituted without departing from the scope of the disclosure. In addition, many modifications may be made to adapt a particular situation or material to the teachings of the disclosure without departing from its scope. Therefore, it is intended that the disclosure not be limited to the particular example(s) disclosed, but that the disclosure will include all examples falling within the scope of the appended claims.

1-20. (canceled)

21. A semiconductor device comprising:
a front side redistribution structure comprising:
a front side conductive layer; and
a front side dielectric layer;
a lower electronic component comprising:
a lower component front side that faces and is coupled to a lower side of the front side redistribution structure and comprises a lower component contact pad;
a lower component back side; and
a plurality of lower component lateral sides extending between the lower component front side and the lower component back side;
a lower insulation layer of a first material that laterally surrounds an entirety of the lower electronic component and comprises an upper side that is vertically higher than the lower component front side;
an upper electronic component comprising:
an upper component front side that faces and is coupled to an upper side of the front side redistribution structure and comprises an upper component contact pad;
an upper component back side; and
a plurality of upper component lateral sides extending between the upper component front side and the upper component back side; and
an upper insulation layer of a second material that laterally surrounds an entirety of the upper component and comprises a lower side that is vertically lower than the upper component front side.

22. The semiconductor device of claim 21, wherein:
the lower insulation layer contacts an entirety of each of the lower component lateral sides; and
the upper insulation layer contacts an entirety of each of the upper component lateral sides.

23. The semiconductor device of claim 21, wherein the lower component back side is exposed from the lower insulation layer.

24. The semiconductor device of claim 21, wherein the upper insulation layer covers the upper component back side.

25. The semiconductor device of claim 21, comprising:
first dielectric material directly vertically between the upper electronic component and the front side redistribution structure; and
second dielectric material directly vertically between the lower electronic component and the front side redistribution structure.

26. The semiconductor device of claim 21, wherein the lower electronic component comprises a die.

27. The semiconductor device of claim 26, wherein the upper component comprises an active component.

28. The semiconductor device of claim 21, wherein:
the lower insulation layer comprises a lateral side;
the upper insulation layer comprises a lateral side;
the front side redistribution structure comprises a lateral side; and
the lateral side of the lower insulation layer, the lateral side of the upper insulation layer, and the lateral side of the front side redistribution structure are coplanar.

29. A semiconductor device comprising:
a front side redistribution structure comprising:
a front side conductive layer; and
a front side dielectric layer;
a lower electronic component comprising:
a lower component front side that faces and is coupled to a lower side of the front side redistribution structure and comprises a lower component contact pad;
a lower component back side; and
a plurality of lower component lateral sides extending between the lower component front side and the lower component back side;
a lower insulation layer of a first material that laterally surrounds an entirety of the lower electronic component;
a first conductive via that runs vertically entirely through the lower insulation layer;
an upper electronic component comprising:
an upper component front side that faces and is coupled to an upper side of the front side redistribution structure and comprises an upper component contact pad;
an upper component back side; and
a plurality of upper component lateral sides extending between the upper component front side and the upper component back side; and
an upper insulation layer of a second material that laterally surrounds an entirety of the upper component.

30. The semiconductor device of claim 29, wherein the first conductive via comprises:
a first lower via end that is vertically lower than the lower component back side; and
a first upper via end that is vertically higher than the lower component front side.

31. The semiconductor device of claim 30, wherein the lower insulation layer comprises an upper side, and further comprising a second conductive via comprising a second lower via end that is coupled to the lower component contact pad, and a second upper via end that is at least as high as the upper side of the lower insulation layer.

32. The semiconductor device of claim 31, wherein the first upper via end and the second upper via end are at a same vertical level.

33. The semiconductor device of claim 31, wherein each of the first conductive via and the second conductive via comprises a plated metal.

34. The semiconductor device of claim 29, wherein the upper insulation layer is free of conductive vias extending vertically entirely through the upper insulation layer.

35. The semiconductor device of claim 29, comprising:
a second dielectric layer on a lower side of the first insulation material; and
a solder coupled to a lower end of the first conductive via and laterally surrounded by the second dielectric layer.

36. The semiconductor device of claim 29, wherein:
the lower insulation layer comprises a lateral side;
the upper insulation layer comprises a lateral side;
the front side redistribution structure comprises a lateral side; and
the lateral side of the lower insulation layer, the lateral side of the upper insulation layer, and the lateral side of the front side redistribution structure are coplanar.

37. A semiconductor device comprising:
a front side redistribution structure comprising:
a front side conductive layer;
a front side dielectric layer; and
a lateral side;
a lower electronic component comprising:
a lower component front side that faces and is coupled to a lower side of the front side redistribution structure and comprises a lower component contact pad;
a lower component back side; and
a plurality of lower component lateral sides extending between the lower component front side and the lower component back side;
a lower insulation layer of a first material that laterally surrounds an entirety of the lower electronic component, the lower insulation layer comprising a lateral side;
an upper electronic component comprising:
an upper component front side that faces and is coupled to an upper side of the front side redistribution structure and comprises an upper component contact pad;
an upper component back side; and
a plurality of upper component lateral sides extending between the upper component front side and the upper component back side;
and
an upper insulation layer of a second material that laterally surrounds an entirety of the upper component, the upper insulation layer comprising a lateral side;
wherein the lateral side of the front side redistribution structure, the lateral side of the lower insulation layer and the lateral side of the upper insulation layer are coplanar.

38. The semiconductor device of claim 37, comprising a lower dielectric layer on a lower side of the first insulation layer, the lower dielectric layer comprising a lateral side that is coplanar with the lateral side of the front side redistribution structure, the lateral side of the lower insulation layer and the lateral side of the upper insulation layer.

39. The semiconductor device of claim 38, comprising an interconnection structure that comprises solder, wherein the lower dielectric layer laterally surrounds the interconnection structure.

40. The semiconductor device of claim 37, comprising:
a first conductive via that runs vertically entirely through the lower insulation layer and comprises a first lower via end and a first upper via end; and
a second conductive via comprising a second lower via end that is coupled to the lower component contact pad, and a second upper via end;
wherein the lower insulation layer comprises an upper side, and the first upper via end and the second upper via end are at least as high as the upper side of the lower insulation layer.
